(19) United States
(12) Patent Application Publication
(10) Pub. No.: US 2023/0422538 A1
(43) Pub. Date: Dec. 28, 2023

(54) ORGANIC ELECTROLUMINESCENT DEVICE

(71) Applicant: BEIJING SUMMER SPROUT TECHNOLOGY CO., LTD., Beijing (CN)

(72) Inventors: Menglan Xie, Beijing (CN); Jing Wang, Beijing (CN); Huiqing Pang, Beijing (CN); Liang Gao, Beijing (CN); Zhihao Cui, Beijing (CN); Hualong Ding, Beijing (CN); Renjie Zheng, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/214,836

(22) Filed: Jun. 27, 2023

(30) Foreign Application Priority Data
Jun. 28, 2022 (CN) 202210740366.7

(51) Int. Cl. H10K 50/12; H10K 50/13; H10K 50/15

(52) U.S. Cl. CPC H10K 50/12; H10K 50/13; H10K 50/156; H10K 2101/30

(57) ABSTRACT

Provided is an organic electroluminescent device. The organic electroluminescent device includes an anode, a cathode, and an organic layer disposed between the anode and cathode; the organic layer includes a first organic layer and a second organic layer; the first organic layer includes a first p-type dopant; the second organic layer includes a second p-type dopant; the first p-type dopant is different from the second dopant; the first organic layer is in contact with the second organic layer, and the second organic layer is above the first organic layer. The organic electroluminescent device including specific p-type dopants and having a specific device structure can significantly improve the overall performance of the device, especially the device lifetime or the device efficiency. Further provided is an electronic assembly including the organic electroluminescent device.

### CROSS-REFERENCE TO RELATED APPLICATION(S)

This application claims priority to Chinese Patent Application No. 202210740366.7 filed on Jun. 28, 2022, the disclosure of which is incorporated herein by reference in its entirety.

### TECHNICAL FIELD

The present application relates to an organic electroluminescent device. More particularly, the present application relates to an organic electroluminescent device having at least two specific organic layers that are in contact with each other, wherein the organic layer includes a specific p-type dopant, and relates to an electronic assembly including the organic electroluminescent device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes, and organic plasmon emitting devices.

An organic electroluminescent device (such as an OLED) is composed of a cathode, an anode, and a series of organic layers stacked between the cathode and the anode, converts electrical energy into light through a voltage applied at both the cathode and the anode of the device, and has the advantages of a wide angle, a high contrast, and a faster response time. In 1987, Tang and Van Slyke of Eastman Kodak reported an organic light-emitting device, which includes an arylamine hole transporting layer and a tris-8-hydroxyquinolato-aluminum layer as an electron transporting layer, and an emissive layer (Applied Physics Letters, 1987, 51 (12): 913-915). Once a voltage is applied across the device, green light was emitted from the device. This device laid a foundation for the development of modern OLEDs. Since the OLED is a self-emitting solid state device, it offers tremendous potential for display and lighting applications. In addition, the inherent properties of organic materials, such as their flexibility, may make them suited for particular applications such as the fabrication of flexible display or lighting on flexible substrates. The OLED has the advantages of a low cost, low power consumption, high brightness, a wide viewing angle, a small thickness, etc. and has been widely applied in the fields of display and lighting after decades of development.

The organic light-emitting diode (OLED) device is generally composed of multiple stacked organic functional layers and includes a hole transporting region and an electron transporting region in addition to a cathode, an anode and an emissive layer (EML). The hole transporting region is located between the anode and the emissive layer and generally includes functional layers such as a hole injection layer (HIL), a hole transporting layer (HTL) and an electron blocking layer (EBL). The electron transporting region is located between the cathode and the emissive layer and generally includes functional layers such as a hole blocking layer (HBL), an electron transporting layer (ETL) and an electron injection layer (EIL). Such functional layers can be set with one or more layers as needed, or no functional layer is present. The hole injection layer and the electron injection layer inject holes and electrons from the anode terminal and the cathode terminal into the device, respectively. The two kinds of carriers migrate to the emissive layer through the transporting layers and form excitons in the emissive layer. The excitons radiate when the excitons drop from the excited state to the ground state and then emit light. The electron blocking layer and the hole blocking layer are generally optional layers. The hole injection layer can be a functional layer including a single material or a functional layer including a variety of materials, and the most commonly used one among the variety of materials is a hole transporting material (HTM) doped with a certain proportion of a p-type dopant. Through the strong electron trapping ability of the p-type dopant, electrons are trapped from the hole transporting material to the p-type doped material, and the concentration of holes in the hole transporting matrix is greatly improved so that the energy level matching of the anode with the organic layers forms good hole injection and transport.

The effective recombination of electrons and holes is an important factor affecting the quantum efficiency of light emission of the device. At present, the carrier balance of the OLED device is mainly improved by the following three methods: the first is to use appropriate electron and hole injection materials to balance the concentration of carriers, the second is to improve electron and hole transporting materials to change the abilities of organic transporting materials to transport carriers to achieve the balance, and the third is to adjust the transporting performance of host materials and/or emissive materials in the emissive layer to achieve the carrier balance. Organic hole transporting materials (HTMs) in the existing OLED device are mostly aromatic amine compounds which have relatively strong electron donation abilities and thus can achieve good hole injection. Assuming that electrons and holes respectively injected from the cathode and the anode have the same concentration, due to differences in performance between materials themselves, a hole mobility in the OLED structure is 1-3 orders of magnitude higher than an electron mobility, that is, the concentration of holes transported to the emissive layer is much greater than that of electrons transported to the emissive layer, resulting in an unbalanced carrier concentration and forming a hole-rich device. The carrier imbalance easily causes carriers to accumulate at an interface between film layers and generate heat, accelerating the aging of the device and causing a reduction in the lifetime, and the carrier imbalance also reduces the recombination probability of excitons, resulting in a decrease in device efficiency. Although carriers can be balanced by improving electron injection and transporting performance, organic materials that can be selected are relatively few. Therefore, effectively reducing the number of holes reaching the light-emitting region is an effective way to improve the carrier balance and enhance the device performance.

The hole injection ability of the HIL in the OLED is regulated generally by doping the HTM with an appropriate amount of a p-type dopant so that the anode is in ohmic contact with the HIL, achieving a good hole injection effect. At present, the single-layer HIL is generally used in the commercial structure, but there is a problem that the regulation of the single-layer HIL on hole injection is very limited. When the concentration of the p-type doped material is low, the ohmic contact cannot be formed, affecting the voltage and lifetime of the device. When the concentration of the p-type doped material is high, although the formation of the ohmic contact is guaranteed, the concentration of holes in the emissive layer is higher than the concentration of electrons due to a large number of holes injected, resulting in carrier imbalance.

In the conventional technology, the thickness of the hole transporting layer is generally increased to balance the electrons and holes in the OLED so that electrons and holes can be effectively combined in the organic layers at the same time without causing hole accumulation. However, the increase in the thickness of the hole transporting layer brings negative effects such as voltage increase, efficiency decrease and even lifetime reduction.

Patent CN100373656C discloses an organic luminous display element. In this patent, the hole injection layer cooperates with the first transporting layer, the hole injection layer uses a fluorinated carbon compound, and the first hole transporting layer uses a p-type dopant. The hole injection is promoted using the hole injection layer, and the device structure is improved using the first hole transporting layer including the p-type dopant. This patent reduces the voltage by introducing the p-doped first hole transporting layer. However, the device disclosed in this patent includes one single p-type doped organic layer, does not disclose that multiple organic layers including the p-type dopant exist in the device, and does not disclose or teach the influence on the device performance when multiple organic layers including the p-type dopant exist.

The related art also discloses some device structures in which multiple organic layers all include a p-type dopant, and the multiple organic layers all include the same p-type dopant material. For example, Patent CN109216565B discloses an organic electroluminescent device. In this patent, the hole injection layer is composed of a first doped layer and a second doped layer; the first doped layer is composed of a p-type dopant to improve the injection of a large number of holes; the second doped layer includes a p-type dopant and a hole transporting material, and the doping proportion is regulated to control the hole injection rate, thereby regulating the balance between electrons and holes and then prolonging the lifetime of the device; the p-type dopants in the first doped layer and the second doped layer are the same p-type dopant material. For another example, a similar device structure is also disclosed in patent application CN107112437A. The embodiments of this application disclose a device structure including two p-type doped organic layers, and the p-type dopants used in the organic layers are also the same. The p-type dopants in the multiple p-type doped layers in the above patents (applications) all are the same material, but the influence on the device performance when the p-type dopants in multiple p-type doped layers are different is not disclosed or taught.

In summary, although the related art discloses some organic electroluminescent devices having a plurality of p-type doped layers, the plurality of p-type doped layers all include the same p-type dopant material. However, when a single p-type dopant material is used in the device, the hole injection ability can be adjusted by adjusting the doping proportion of the p-type dopant, but when the p-type dopant is doped such that the p-type dopant reaches a certain concentration, the hole injection cannot be regulated, so the ability to regulate hole injection through a single p-type dopant is limited.

### SUMMARY

To solve the preceding problems, the present disclosure aims to provide a new organic electroluminescent device. The organic electroluminescent device includes an anode, a cathode, and organic layers disposed between the anode and cathode; the organic layers include a first organic layer and a second organic layer that are in direct contact with each other; the first organic layer includes a first p-type dopant; the second organic layer includes a second p-type dopant; the first p-type dopant is different from the second dopant; the lowest unoccupied molecular orbital (LUMO) energy levels of the first p-type dopant and the second p-type dopant are less than −4.35 eV. At least two p-type doped layers are introduced into the organic electroluminescent device, and the p-type dopants used in these two layers are different, such that the regulation of the hole injection ability of the device is improved, thereby providing more space for the regulation of the hole injection ability of the device. For example, different p-type dopants are selected for appropriate matching, and the concentrations of p-type dopants in multiple p-type doped layers are adjusted to better regulate the hole injection ability, achieving the carrier balance and improving the comprehensive performance of the device.

According to an embodiment of the present disclosure, an organic electroluminescent device is provided. The organic electroluminescent device includes an anode, a cathode, and a first organic layer and a second organic layer disposed between the anode and the cathode;
wherein the first organic layer includes a first p-type dopant;
the second organic layer includes a second p-type dopant;
the first p-type dopant is different from the second p-type dopant;
the LUMO energy levels of the first p-type dopant and the second p-type dopant are less than −4.35 eV; and
the first organic layer is in contact with the second organic layer.

According to an embodiment of the present disclosure, an electronic assembly is further disclosed. The electronic assembly includes the organic electroluminescent device described in the preceding embodiment.

The present disclosure provides a new organic electroluminescent device. The organic electroluminescent device includes an anode, a cathode, and organic layers disposed between the anode and cathode; the organic layers include a first organic layer and a second organic layer that are in direct contact with each other; the first organic layer includes a first p-type dopant; the second organic layer includes a second p-type dopant; the first p-type dopant is different from the second dopant; the LUMO energy levels of the first p-type dopant and the second p-type dopant are less than −4.35 eV. At least two p-type doped layers are introduced into the organic electroluminescent device, and the p-type dopants used in these two layers are different to improve the regulation of the hole injection ability of the device and provide more space for the regulation of the hole injection ability of the device, thereby significantly improving the comprehensive performance of the device and especially improving the lifetime of the device. For example, different p-type dopants are selected for appropriate matching, and the concentrations of p-type dopants in multiple p-type doped layers are adjusted to better regulate the hole injection ability, achieving the carrier balance and improving the comprehensive performance of the device.

### BRIEF DESCRIPTION OF DRAWINGS

FIG. 1 is a schematic diagram of an organic light-emitting device 100.

FIG. 2 is a schematic diagram of an organic light-emitting device 200.

FIG. 3 is a schematic diagram of an organic electroluminescence device 300.

FIG. 4 is a schematic diagram of a stacked organic electroluminescence device 400.

### DETAILED DESCRIPTION

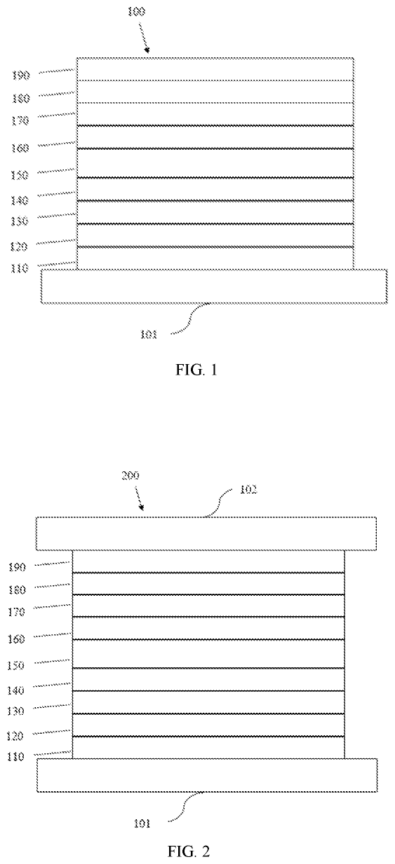

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. The device 100 may include a substrate 101, an anode 110, a hole injection layer 120, a hole transporting layer 130, an electron blocking layer 140 (optional), an emissive layer 150, a hole blocking layer 160 (optional), an electron transporting layer 170, an electron injection layer 180, and a cathode 190. The device 100 may be fabricated by depositing the layers described in order. In some applications, the hole injection layer 120 and the hole transporting layer 130 are collectively referred to as the hole transporting layer or referred to as a first hole transporting layer and a second hole transporting layer. However, the hole injection layer and the hole transporting layer have a relatively large difference: generally, the hole injection layer is in direct contact with the anode and is generally thinner than the hole transporting layer. The properties and functions of the layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-type doped hole transporting layer is m-MTDATA doped with F₄-TCNQ at a molar ratio of 1:50, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transporting layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. For example, the hole blocking layer is not a necessary layer and can be omitted in some structures. It may also include other layers not specifically described. Within each layer, a single material or a mixture of multiple materials can be used to achieve optimum performance. Any functional layer may include several sublayers. For example, the emissive layer may have two layers of different emissive materials to achieve desired emission spectrum.

In one embodiment, an OLED may be described as having an “organic layer” disposed between a cathode and an anode. The organic layer may comprise a single layer or multiple layers.

An OLED can be encapsulated by a bather layer. FIG. 2 schematically shows an organic light-emitting device 200 without limitation. FIG. 2 differs from FIG. 1 in that the organic light-emitting device include a barrier layer 102, which is above the cathode 190, to protect it from harmful species from the environment, such as moisture and oxygen. Any material that can provide the barrier function can be used as the barrier layer, such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3D displays, vehicles displays, and vehicle tail lights.

The materials and structures described herein may be used in other organic electronic devices listed above.

There are various methods for OLED fabrication. Small molecule OLEDs are generally fabricated by vacuum thermal evaporation. Polymer OLEDs are fabricated by solution process such as spin coating, inkjet printing, and slit printing. If the material can be dissolved or dispersed in a solvent, the small molecule OLED can also be produced by solution process. Organic layers in the organic electroluminescent device provided by the present application can be prepared by evaporation or solution process. For example, a first organic layer and a second organic layer in the present application can be prepared by evaporation or solution process as required.

Herein, energy levels of a compound (a lowest unoccupied molecular orbital (LUMO) energy level and a highest occupied molecular orbital (HOMO) energy level) are measured by a cyclic voltammetry method. For example, the LUMO energy level of the compound HATCN

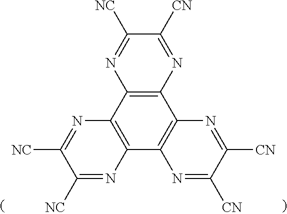 [SMILES: N#Cc1nc2c3nc(C#N)c(C#N)nc3c3nc(C#N)c(C#N)nc3c2nc1C#N]

measured by the test method of the present application is −4.33 eV. Herein, all “LUMO energy levels” and “HOMO energy levels” are expressed as negative values, and the smaller the numerical value (i.e., the larger the absolute value), the deeper the energy level. Herein, the expression that the energy level is smaller than a certain number means that the numerical value of the energy level is smaller than this number, i.e., is more negative. For example, the LUMO energy level of a certain organic material is <−4.5 eV, which means that the numerical value of the LUMO energy level of the organic material is equal to −4.5 eV or more negative than −4.5 eV, that is, the LUMO energy level of the organic material is deeper than 4.5 eV.

The term “doping proportion” refers to the percentage of a material in an organic layer to the total mass of the organic layer. For example, the doping proportion of a first p-type dopant in a first organic layer, which is mentioned in the present application, refers to the percentage of the first p-type dopant to the total mass of the first organic layer; when the first organic layer is composed of a first organic material and the first p-type dopant, the total mass of the first organic layer is the sum of the mass of the first organic material and the mass of the first p-type dopant. When the first organic layer is composed of the first p-type dopant only, the doping ratio of the first p-type dopant in the first organic layer is 100%. When the second organic layer is composed of the second p-type dopant only, the doping ratio of the second p-type dopant in the second organic layer is 100%.

In the present application, the term “the same as” or “different from” is used in the context of a material, for example, that “a first p-type dopant is different from a second p-type dopant” or that “a first organic material is the same as or different from a second organic material”. The term “the same as” therein refers to that two or more materials have the same chemical structural formula, or two or more materials differ only in that hydrogens in the chemical structural formula are partially or fully substituted with deuterium. Conversely, the term “different from” therein refers to that the organic materials used have different chemical structural formulas (that is, the chemical structural formulas differ not only in that hydrogens in the molecular formula are partially or fully substituted with deuterium).

In the present application, the expression that organic layers are “different” means that: if each organic layer comprises a single material, it means that the organic layers comprise different materials; if each organic layer is a composite material/layer comprising at least two materials, it means that at least one of the materials comprised in the organic layer is different or the composite materials/layers formed in the organic layers are different (the composite materials/layers comprise different materials and/or have different doping proportions). The expression that organic layers are “the same” means that the organic layers comprise the same materials and have the same doping proportion.

As used herein, the “p-type dopant” refers to a dopant with an oxidation ability, which has a strong electron withdrawing ability and is an electron acceptor. The “p-type dopant” refers to a molecular p-type dopant herein.

As used herein, the “molecular p-type dopant” refers to an organic compound composed of more than 6 atoms in a dopant molecule. Preferably, the number of atoms forming the dopant molecule is greater than 10. More preferably, the number of atoms forming the dopant molecule is greater than 20. Preferably, the molar mass of the “molecular p-type organic dopant” is between 200 g/mol and 2000 g/mol, preferably between 300 g/mol and 1800 g/mol, more preferably between 400 g/mol and 1500 g/mol.

As used herein, “top” means furthest away from the anode, while “bottom” means closest to the anode. Where a second layer is described as “disposed above” a first layer, the first layer is closer to the anode. Conversely, where the second layer is described as “disposed below” the first layer, the second layer is closer to the anode. There may be other layers between the first layer and the second layer, unless it is specified that the first layer is “in contact with” the second layer. For example, a cathode may be described as “disposed above” the anode even though there are various organic layers therebetween.

As used herein, the “emissive unit” refers to an organic material layer that emits light by applying a voltage or current. The “emissive unit” includes at least an emissive layer, and the emissive layer may further include a host material and an emissive material. The “emissive unit” further includes at least a pair of hole and electron injection/transporting layers, for example, a hole injection layer, a hole transporting layer, an electron blocking layer, a hole blocking layer, an electron transporting layer, and an electron injection layer.

As used herein, the “charge generation layer (CGL)” is a layer disposed between two emissive units to provide electrons and holes and is composed of an n-type charge generation layer and a p-type charge generation layer. The n-type charge generation layer is in contact with the electron transporting layer or electron injection layer of one emissive unit, and the p-type charge generation layer is generally in contact with the hole injection layer or hole transporting layer of an adjacent emissive unit and provides holes for the adjacent emissive unit. The p-type charge generation layer may be a p-type dopant of a single material or a composite layer of a hole transporting material doped with a p-type dopant.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-b eta-naphthylethyl, 1-beta-naphthyl isopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzonlquinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfanyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

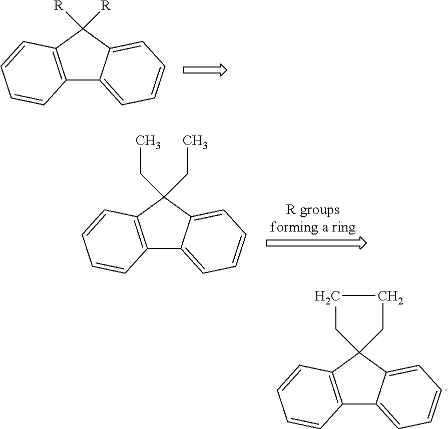

The expression that adjacent substituents can be optionally joined to form a ring is also intended to mean that two substituents bonded to carbon atoms which are directly bonded to each other are joined to each other via a chemical bond to form a ring, which can be exemplified by the following formula:

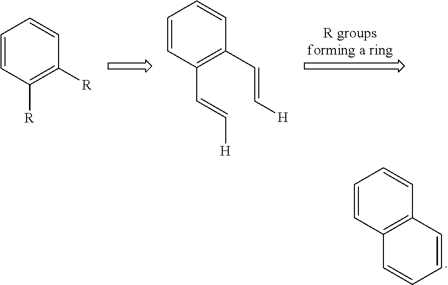

The expression that adjacent substituents can be optionally joined to form a ring is also intended to mean that two substituents bonded to a further distant carbon atom are joined to each other via a chemical bond to form a ring, which can be exemplified by the following formula:

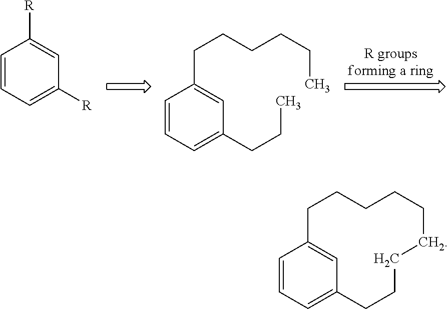

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

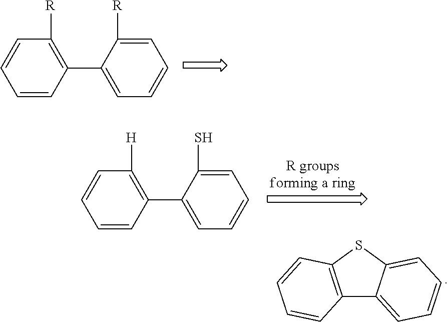

According to an embodiment of the present disclosure, an organic electroluminescent device is provided. The organic electroluminescent device includes an anode, a cathode, and a hole transporting region disposed between the anode and the cathode;
wherein the hole transporting region includes a first organic layer and a second organic layer;
wherein the first organic layer includes a first p-type dopant;
the second organic layer includes a second p-type dopant;
the first p-type dopant is different from the second p-type dopant;
the LUMO energy levels of the first p-type dopant and the second p-type dopant are less than −4.35 eV; and
the first organic layer is in contact with the second organic layer.

According to an embodiment of the present disclosure, the sum of the thickness of the first organic layer and the thickness of the second organic layer is not greater than 100 nm.

According to an embodiment of the present disclosure, the sum of the thickness of the first organic layer and the thickness of the second organic layer is not greater than 50 nm.

According to an embodiment of the present disclosure, the sum of the thickness of the first organic layer and the thickness of the second organic layer is not greater than 30 nm.

According to an embodiment of the present disclosure, the sum of the thickness of the first organic layer and the thickness of the second organic layer is not greater than 20 nm.

According to an embodiment of the present disclosure, the first p-type dopant and the second p-type dopant are molecular p-type dopants.

According to an embodiment of the present disclosure, the sum of the thickness of the first organic layer and the thickness of the second organic layer is greater than or equal to 5 nm.

According to an embodiment of the present disclosure, the sum of the thickness of the first organic layer and the thickness of the second organic layer is greater than or equal to 10 nm.

According to an embodiment of the present disclosure, the LUMO energy level of the first p-type dopant and/or the LUMO energy level of the second p-type dopant are less than or equal to −4.4 eV.

According to an embodiment of the present disclosure, the LUMO energy level of the first p-type dopant and/or the LUMO energy level of the second p-type dopant are less than or equal to −4.5 eV.

According to an embodiment of the present disclosure, the LUMO energy level of the first p-type dopant and/or the LUMO energy level of the second p-type dopant are less than or equal to −4.6 eV.

According to an embodiment of the present disclosure, the LUMO energy level of the first p-type dopant and/or the LUMO energy level of the second p-type dopant are less than or equal to −4.8 eV.

According to an embodiment of the present disclosure, the first organic layer is in contact with the anode.

According to an embodiment of the present disclosure, the doping proportion of the first p-type dopant in the first organic layer is greater than or equal to the doping proportion of the second p-type dopant in the second organic layer.

According to an embodiment of the present disclosure, the doping proportion of the first p-type dopant in the first organic layer is less than the doping proportion of the second p-type dopant in the second organic layer.

According to an embodiment of the present disclosure, the doping proportion of the first p-type dopant in the first organic layer is greater than or equal to 0.1% and less than or equal to 60%.

According to an embodiment of the present disclosure, the doping proportion of the first p-type dopant in the first organic layer is greater than or equal to 0.5% and less than or equal to 50%.

According to an embodiment of the present disclosure, the doping proportion of the first p-type dopant in the first organic layer is greater than or equal to 1% and less than or equal to 30%.

According to an embodiment of the present disclosure, the doping proportion of the second p-type dopant in the second organic layer is greater than or equal to 0.1% and less than or equal to 60%.

According to an embodiment of the present disclosure, the doping proportion of the second p-type dopant in the second organic layer is greater than or equal to 0.5% and less than or equal to 50%.

According to an embodiment of the present disclosure, the doping proportion of the second p-type dopant in the second organic layer is greater than or equal to 1% and less than or equal to 30%.

According to an embodiment of the present disclosure, the second organic layer is above the first organic layer.

According to an embodiment of the present disclosure, the LUMO energy level of the first p-type dopant is greater than or equal to the LUMO energy level of the second p-type dopant.

According to an embodiment of the present disclosure, the LUMO energy level of the first p-type dopant is less than or equal to the LUMO energy level of the second p-type dopant.

According to an embodiment of the present disclosure, the doping proportion of the first p-type dopant in the first organic layer is less than or equal to the doping proportion of the second p-type dopant in the second organic layer.

When a low concentration of p-type dopant is used in the first organic layer (i.e., the lower layer close to the anode), the number of injected holes can be controlled, and when a high concentration of p-type dopant is used in the second organic layer (i.e., the upper layer close to the cathode), the number of injected holes can be balanced.

According to an embodiment of the present disclosure, the doping proportion of the first p-type dopant in the first organic layer is greater than or equal to the doping proportion of the second p-type dopant in the second organic layer.

According to an embodiment of the present disclosure, the LUMO of the first p-type dopant is greater than −5.2 eV.

According to an embodiment of the present disclosure, the LUMO of the first p-type dopant is greater than or equal to −5.1 eV.

According to an embodiment of the present disclosure, the LUMO of the first p-type dopant is greater than or equal to −5.0 eV.

According to an embodiment of the present disclosure, the LUMO of the second p-type dopant is greater than −5.2 eV.

According to an embodiment of the present disclosure, the LUMO of the second p-type dopant is greater than or equal to −5.1 eV.

According to an embodiment of the present disclosure, the LUMO of the second p-type dopant is greater than or equal to −5.0 eV.

According to an embodiment of the present disclosure, the LUMO of the first p-type dopant and/or the LUMO of the second p-type dopant are less than or equal to −4.35 eV.

According to an embodiment of the present disclosure, the LUMO of the first p-type dopant and/or the LUMO of the second p-type dopant are less than or equal to −4.5 eV.

According to an embodiment of the present disclosure, the first organic layer further includes a first organic material.

According to an embodiment of the present disclosure, the second organic layer further includes a second organic material.

According to an embodiment of the present disclosure, the HOMO energy level of the first organic material and/or the HOMO energy level of the second organic material are greater than or equal to −4.5 eV.

According to an embodiment of the present disclosure, the HOMO energy level of the first organic material and/or the HOMO energy level of the second organic material are greater than or equal to −4.8 eV.

According to an embodiment of the present disclosure, the doping proportion of the first p-type dopant in the first organic layer is greater than or equal to 0.01% and less than or equal to 99.9%.

According to an embodiment of the present disclosure, the doping proportion of the first p-type dopant in the first organic layer is greater than or equal to 0.1% and less than or equal to 99.9%.

According to an embodiment of the present disclosure, the doping proportion of the first p-type dopant in the first organic layer is greater than or equal to 0.5% and less than or equal to 50%.

According to an embodiment of the present disclosure, the doping proportion of the second p-type dopant in the second organic layer is greater than or equal to 0.01% and less than or equal to 99.9%.

According to an embodiment of the present disclosure, the doping proportion of the second p-type dopant in the second organic layer is greater than or equal to 0.1% and less than or equal to 99.9%.

According to an embodiment of the present disclosure, the doping proportion of the second p-type dopant in the second organic layer is greater than or equal to 0.5% and less than or equal to 50%.

According to an embodiment of the present disclosure, the electroluminescent device further includes an emissive layer disposed between the hole transporting region and the cathode.

According to an embodiment of the present disclosure, the emissive layer includes an emissive material, and the emissive material is a phosphorescent material, a fluorescent material or a delayed fluorescent material.

According to an embodiment of the present disclosure, the electroluminescent device further includes a third organic layer disposed between the anode and the emissive layer, and the third organic layer includes a third p-type dopant.

According to an embodiment of the present disclosure, the third organic layer further includes a third organic material.

According to an embodiment of the present disclosure, the third p-type dopant is the same as or different from the first p-type dopant.

According to an embodiment of the present disclosure, the third p-type dopant is the same as or different from the second p-type dopant.

According to an embodiment of the present disclosure, the third organic material is the same as or different from the first organic material.

According to an embodiment of the present disclosure, the third organic material is the same as or different from the second organic material.

According to an embodiment of the present disclosure, the organic electroluminescent device may have more than two organic layers including a p-type dopant, for example, three, four or five organic layers including a p-type dopant. When the organic electroluminescent device has more than two organic layers including a p-type dopant, for example, when a third organic layer is further included above the second organic layer, the third organic layer includes a third organic material and a third p-type dopant. The doping proportions of the p-type dopants in more than two organic layers may increase at a gradient along the direction from the anode to the cathode, or may also decrease at a gradient along the direction from the anode to the cathode, or may also change as a parabolic curve (i.e. the doping proportion increases first and then decreases or the doping proportion decreases first and then increases). Of course, the doping proportions may be consistent as required.

According to an embodiment of the present disclosure, the organic electroluminescent device further includes a charge generation layer, and the charge generation layer includes a p-type charge generation layer.

According to an embodiment of the present disclosure, the p-type charge generation layer includes the first p-type dopant or the second p-type dopant.

According to an embodiment of the present disclosure, the first organic layer or the second organic layer is in contact with the p-type charge generation layer.

According to an embodiment of the present disclosure, the doping proportion of the first p-type dopant or the doping proportion of the second p-type dopant in the p-type charge generation layer in the charge generation layer is greater than or equal to 0.01% and less than or equal to 100%.

According to an embodiment of the present disclosure, the first organic material is the same as the second organic material.

According to an embodiment of the present disclosure, the first organic material is different from the second organic material.

According to an embodiment of the present disclosure, the organic electroluminescent device has the following single-layer device structure: anode/first organic layer/second organic layer/hole transporting layer/electron blocking layer/emissive layer/hole blocking layer/electron transporting layer/electron injection layer/cathode, wherein the structure of the layers as described may be present or not as needed, for example, the electron blocking layer and the hole blocking layer are optional layers and can be selected as needed. The structure of the layers as described is not limited to a single-layer structure, for example, the emissive layer may be a two-layer structure, i.e., the emissive layer includes two emissive layers. The third organic layer of the present disclosure may be further included between the second organic layer and the hole transporting layer.

According to an embodiment of the present disclosure, the organic electroluminescence device has the following stacked device structure: anode/first emissive unit/charge generation layer/second emissive unit/cathode. The first emissive unit and the second emissive unit may be the same or different and each independently have the organic layer structure between the anode and the cathode in the single-layer device structure described above. A first charge generation layer and a third emissive unit may be further included between the second emissive unit and the cathode, i.e., the device structure is as follows: anode/first emissive unit/charge generation layer/second emissive unit/first charge generation layer/third emissive unit/cathode, wherein the third emissive unit and the first emissive unit may be the same or different, and the third emissive unit and the second emissive unit may also be the same or different.

According to an embodiment of the present disclosure, an electronic assembly is disclosed. The electronic assembly includes the organic electroluminescent device described in any one of the preceding embodiments.

According to an embodiment of the present disclosure, the p-type dopant has the structure represented by Formula 1:

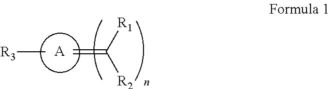

wherein n is selected from an integer from 1 to 5;
ring A is, at each occurrence identically or differently, selected from a conjugated ring having 3 to 30 ring atoms;
R₃ represents mono-substitution, multiple substitutions or non-substitution;
R₁, R₂ and R₃ are, at each occurrence identically or differently, selected from hydrogen, deuterium or a substituent;
adjacent substituents R₁, R₂, R₃ can be optionally joined to form a ring.

The expression that “ring A is a conjugated ring having 3 to 30 ring atoms” herein is intended to mean that the ring A is a cyclic structure having 3 to 30 ring atoms and the ring A has the structural feature of being conjugated. For example, the ring A includes, but is not limited to, the structures represented by Formula 2 to Formula 14 in the present application. The ring A may be a monocyclic structure or a polycyclic structure, wherein the polycyclic structure may be a parallel-ring structure or a fused-ring structure or may be an integrally conjugated structure formed by connecting two conjugated rings by a double bond, for example, the structure represented by Formula 13 in the present application. The ring A may be a carbocyclic ring or a heterocyclic ring.

The expression that “adjacent substituents R₁, R₂, R₃ can be optionally joined to form a ring” herein is intended to mean that any one or more of groups of adjacent substituents, such as substituents R₃, substituents R₁ and R₂, and substituents R₁ and R₃, can be joined to form a ring. Obviously, it is also possible that none of these substituents are joined to form a ring.

According to an embodiment of the present disclosure, the substituent is an electron-withdrawing group.

According to an embodiment of the present disclosure, n is selected from 1, 2, or 3.

According to an embodiment of the present disclosure, n is selected from 1 or 2.

According to an embodiment of the present disclosure, the ring A is, at each occurrence identically or differently, selected from a conjugated ring having 3 to 20 ring atoms.

According to an embodiment of the present disclosure, the ring A is, at each occurrence identically or differently, selected from a conjugated ring having 4 to 20 ring atoms.

According to an embodiment of the present disclosure, R₁ and/or R₂ are a substituent comprising at least one electron withdrawing group.

According to an embodiment of the present disclosure, a Hammett constant of the electron withdrawing group is ≥0.05, preferably ≥0.3, more preferably ≥0.5.

In the present disclosure, the Hammett substituent constant value of the electron withdrawing group is ≥0.05, for example, ≥0.1 or ≥0.2; preferably ≥0.3; more preferably ≥0.5. The electron withdrawing ability is relatively strong, which can significantly reduce the LUMO energy level of the compound and achieve the improvement of a charge mobility.

It is to be noted that the Hammett substituent constant value includes a para constant and/or a meta constant of a Hammett substituent, and as long as the para constant and the meta constant are greater than 0 and one of the para constant and the meta constant is greater than or equal to 0.05, the Hammett substituent can be used as the group selected in the present disclosure.

According to an embodiment of the present disclosure, the electron withdrawing group is selected from the group consisting of: halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, an aza-aromatic ring group, and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, and an aza-aromatic ring group: alkyl having 1 to 20 carbon atoms, cycloalkyl having 3 to 20 ring carbon atoms, heteroalkyl having 1 to 20 carbon atoms, a heterocyclic group having 3 to 20 ring atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms, and combinations thereof.

According to an embodiment of the present disclosure, the electron withdrawing group is selected from the group consisting of: halogen, a nitroso group, a nitro group, an acyl group, a carbonyl group, a carboxylic acid group, an ester group, SF₅, a boranyl group, a sulfinyl group, a sulfonyl group, a phosphoroso group, an aza-aromatic ring group, and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms, and combinations thereof.

According to an embodiment of the present disclosure, the electron withdrawing group is selected from the group consisting of: fluorine, an acyl group, a carbonyl group, an ester group, SF₅, a boranyl group, an aza-aromatic ring group, and any one of the following groups substituted with one or more of fluorine, a cyano group, an isocyano group, SCN, OCN, SF₅, CF₃, OCF₃, SCF₃, and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms, and combinations thereof.

According to an embodiment of the present disclosure, the ring A is, at each occurrence identically or differently, selected from the group consisting of Formula 2 to Formula 14:

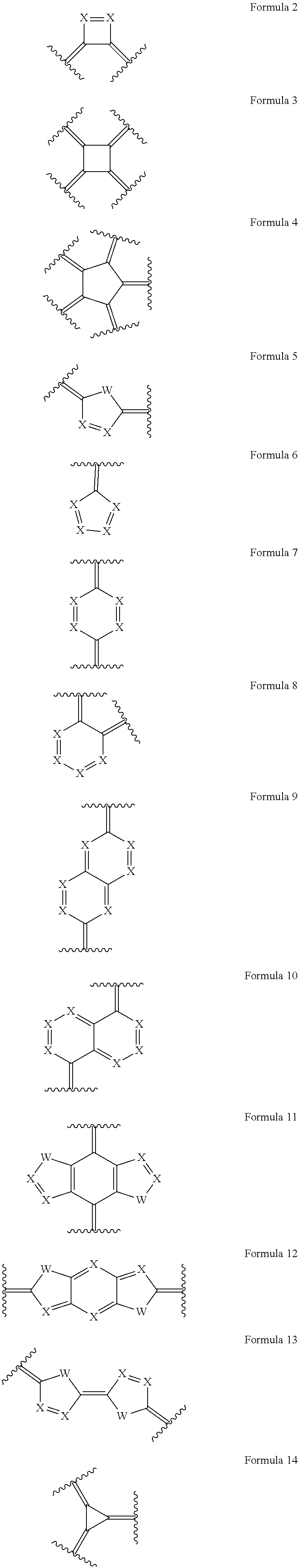

wherein
X is, at each occurrence identically or differently, selected from the group consisting of N and CR₃;
W is, at each occurrence identically or differently, selected from the group consisting of O, S, Se and NR₃;
R₃ represents mono-substitution, multiple substitutions or non-substitution;
R₁, R₂ and R₃ are, at each occurrence identically or differently, selected from hydrogen, deuterium or a substituent;
adjacent substituents R₁, R₂, R₃ can be optionally joined to form a ring;
“ [symbol] ” represents a position where the double bond in Formula 2 to Formula 14 is joined to the double bond in Formula 1.

According to an embodiment of the present disclosure, the p-type dopant has a structure selected from the structures represented by the following formulas:

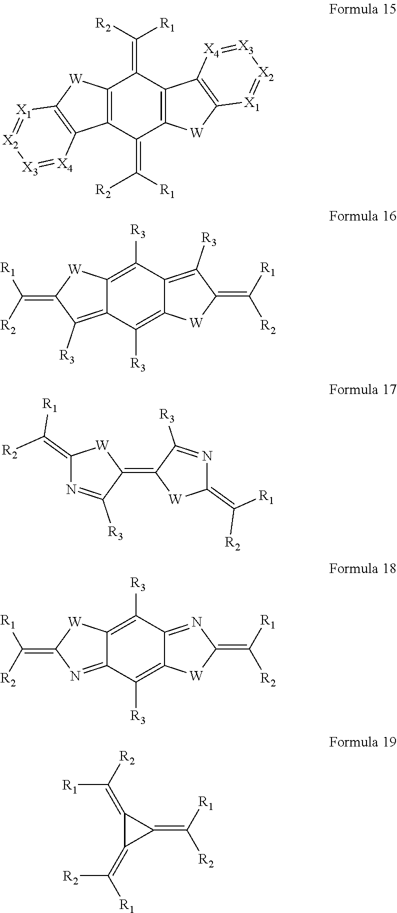

wherein
X₁, X₂, X₃ and X₄ are, at each occurrence identically or differently, selected from the group consisting of N and CR₃;
W is, at each occurrence identically or differently, selected from the group consisting of O, S, Se and NR₃;
R₁, R₂ and R₃ are, at each occurrence identically or differently, selected from hydrogen, deuterium or a substituent;
adjacent substituents R₁, R₂, R₃ can be optionally joined to form a ring.

According to an embodiment of the present disclosure, the substituent is halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, or combinations thereof.

According to an embodiment of the present disclosure, W is, at each occurrence identically or differently, selected from O, S, or Se.

According to an embodiment of the present disclosure, W is, at each occurrence identically or differently, selected from O or S.

According to an embodiment of the present disclosure, W is selected from O.

According to an embodiment of the present disclosure, W is, at each occurrence identically or differently, selected from NR₃, and R₃ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, W is, at each occurrence identically or differently, selected from NR₃, and R₃ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, the p-type dopant is selected from the group consisting of, but not limited to, the following structures:

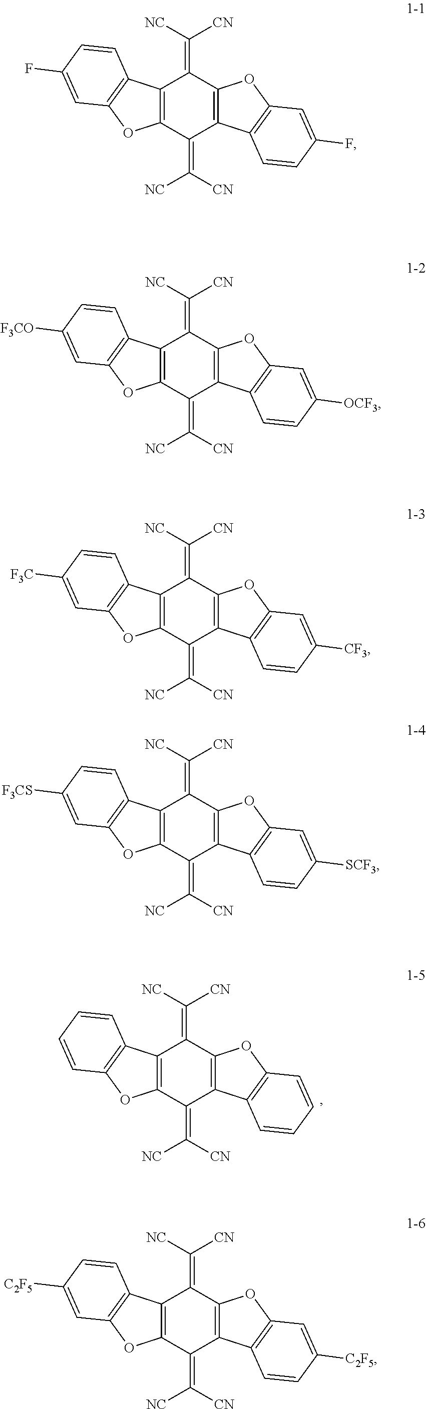

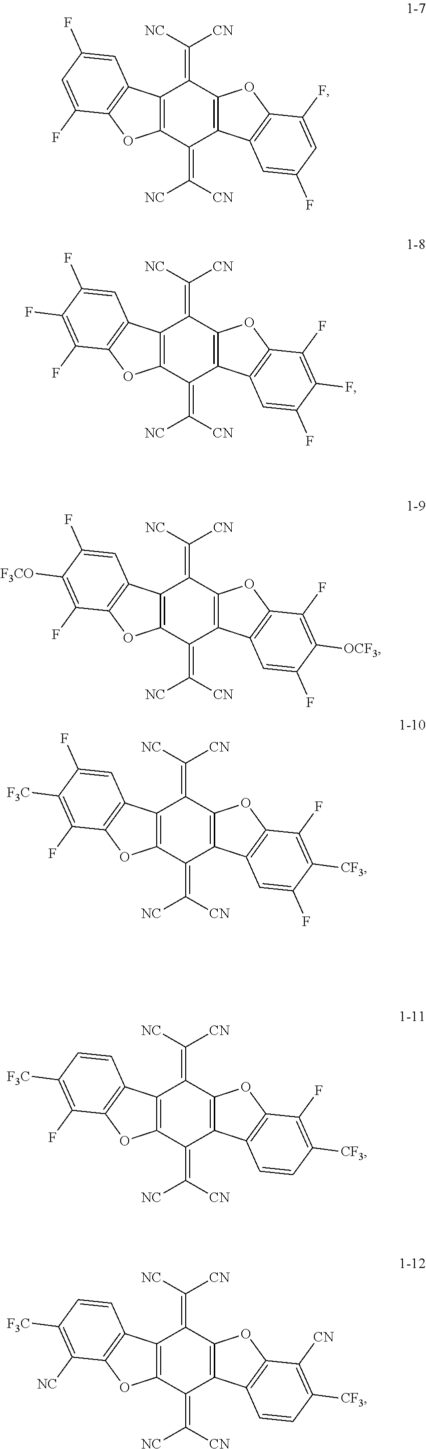 [SMILES: N#CC(C#N)=c1c2oc3c(F)cc(F)cc3c2c(=C(C#N)C#N)c2oc3c(F)cc(F)cc3c12 ; N#CC(C#N)=c1c2oc3c(F)c(F)c(F)cc3c2c(=C(C#N)C#N)c2oc3c(F)c(F)c(F)cc3c12 ; N#CC(C#N)=c1c2oc3c(F)c(OC(F)(F)F)c(F)cc3c2c(=C(C#N)C#N)c2oc3c(F)c(OC(F)(F)F)c(F)cc3c12 ; N#CC(C#N)=c1c2oc3c(F)c(C(F)(F)F)c(F)cc3c2c(=C(C#N)C#N)c2oc3c(F)c(C(F)(F)F)c(F)cc3c12 ; N#CC(C#N)=c1c2oc3c(F)c(C(F)(F)F)ccc3c2c(=C(C#N)C#N)c2oc3c(F)c(C(F)(F)F)ccc3c12 ; N#CC(C#N)=c1c2oc3c(C#N)c(C(F)(F)F)ccc3c2c(=C(C#N)C#N)c2oc3c(C#N)c(C(F)(F)F)ccc3c12]

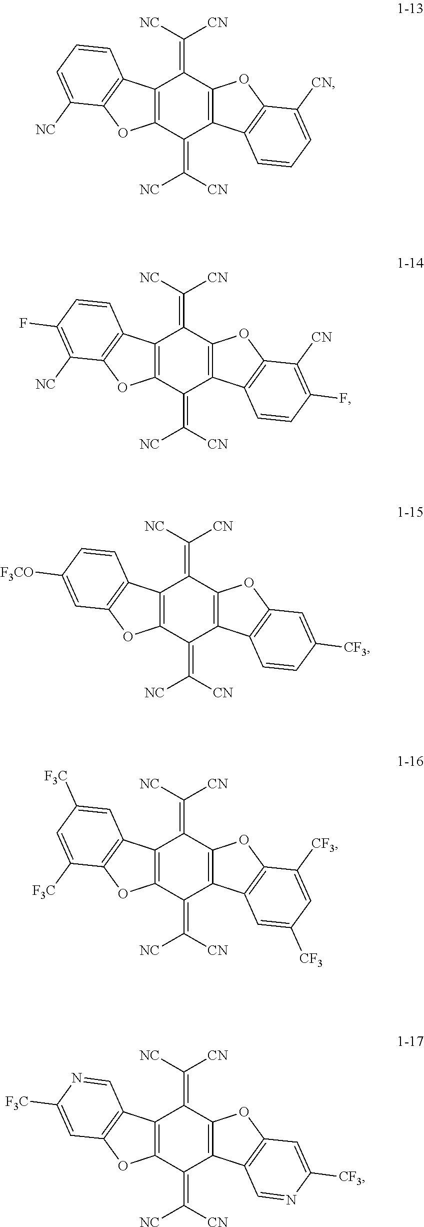 [SMILES: N#CC(C#N)=c1c2oc3c(C#N)cccc3c2c(=C(C#N)C#N)c2oc3c(C#N)cccc3c12 ; N#CC(C#N)=c1c2oc3c(C#N)c(F)ccc3c2c(=C(C#N)C#N)c2oc3c(C#N)c(F)ccc3c12 ; N#CC(C#N)=c1c2oc3cc(C(F)(F)F)ccc3c2c(=C(C#N)C#N)c2oc3cc(OC(F)(F)F)ccc3c12 ; N#CC(C#N)=c1c2oc3c(C(F)(F)F)cc(C(F)(F)F)cc3c2c(=C(C#N)C#N)c2oc3c(C(F)(F)F)cc(C(F)(F)F)cc3c12 ; N#CC(C#N)=c1c2oc3cc(C(F)(F)F)ncc3c2c(=C(C#N)C#N)c2oc3cc(C(F)(F)F)ncc3c12]

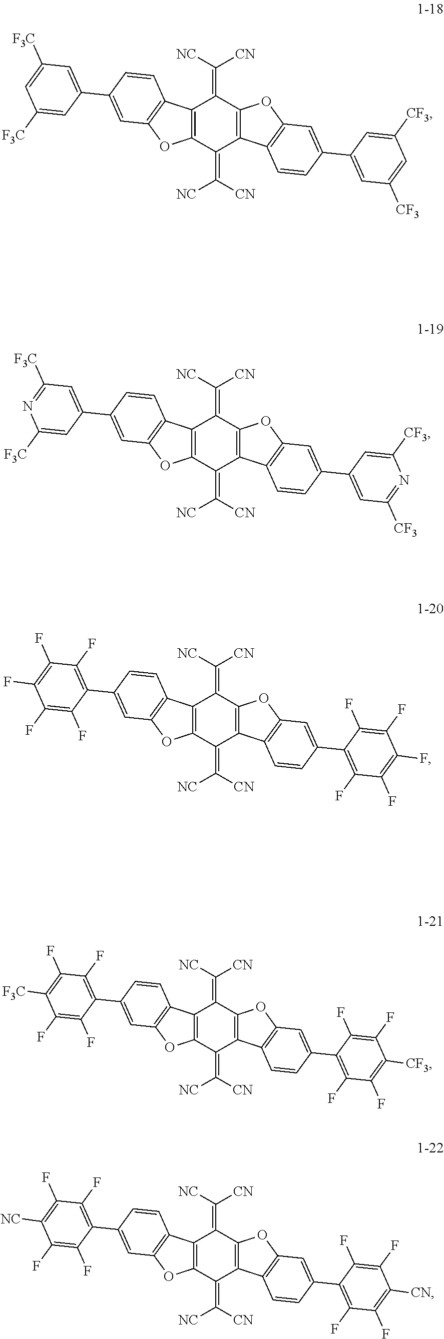

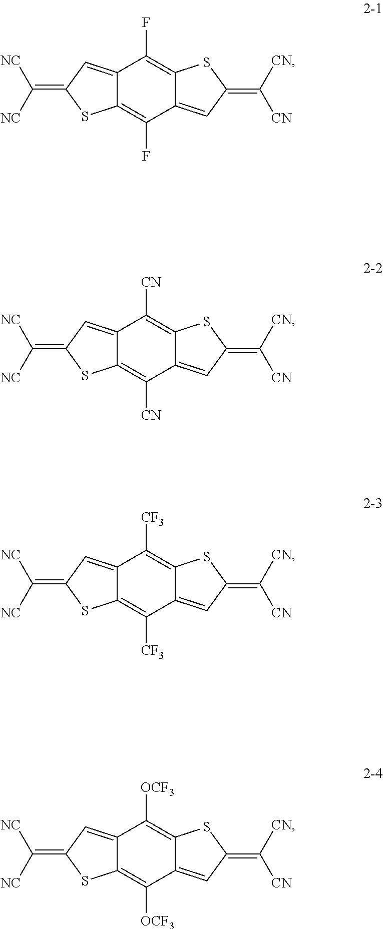 [SMILES: N#CC(C#N)=c1cc2c(F)c3sc(=C(C#N)C#N)cc3c(F)c2s1 ; N#CC(C#N)=c1cc2c(C#N)c3sc(=C(C#N)C#N)cc3c(C#N)c2s1 ; N#CC(C#N)=c1cc2c(C(F)(F)F)c3sc(=C(C#N)C#N)cc3c(C(F)(F)F)c2s1 ; N#CC(C#N)=c1cc2c(OC(F)(F)F)c3sc(=C(C#N)C#N)cc3c(OC(F)(F)F)c2s1]

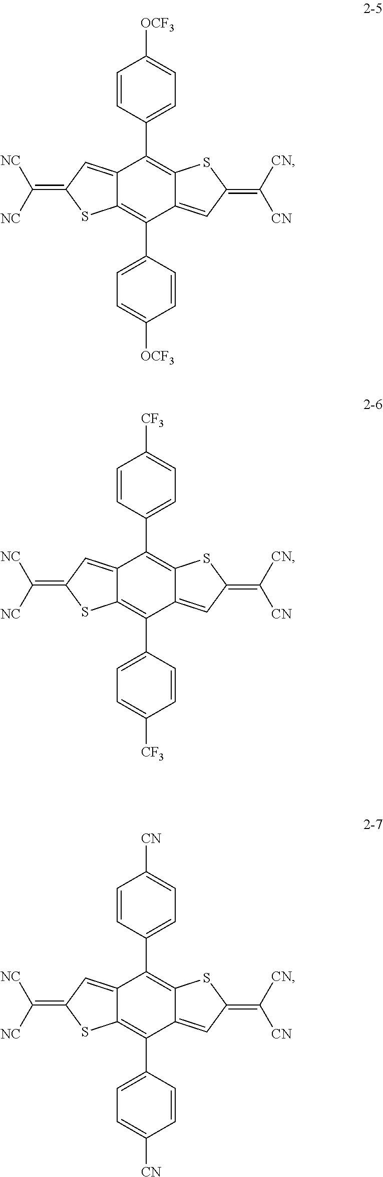 [SMILES: N#CC(C#N)=c1cc2c(-c3ccc(OC(F)(F)F)cc3)c3sc(=C(C#N)C#N)cc3c(-c3ccc(OC(F)(F)F)cc3)c2s1 ; N#CC(C#N)=c1cc2c(-c3ccc(C(F)(F)F)cc3)c3sc(=C(C#N)C#N)cc3c(-c3ccc(C(F)(F)F)cc3)c2s1 ; N#CC(C#N)=c1cc2c(-c3ccc(C#N)cc3)c3sc(=C(C#N)C#N)cc3c(-c3ccc(C#N)cc3)c2s1]

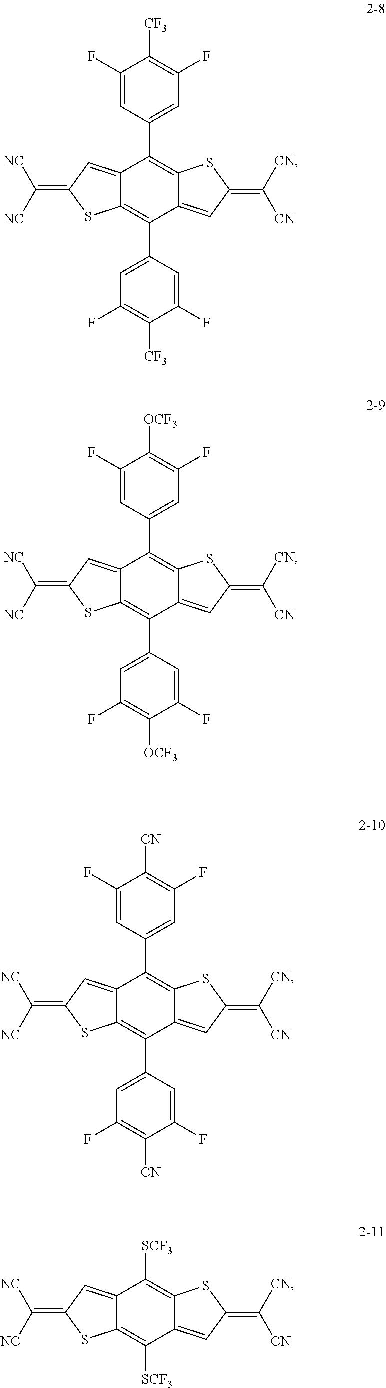

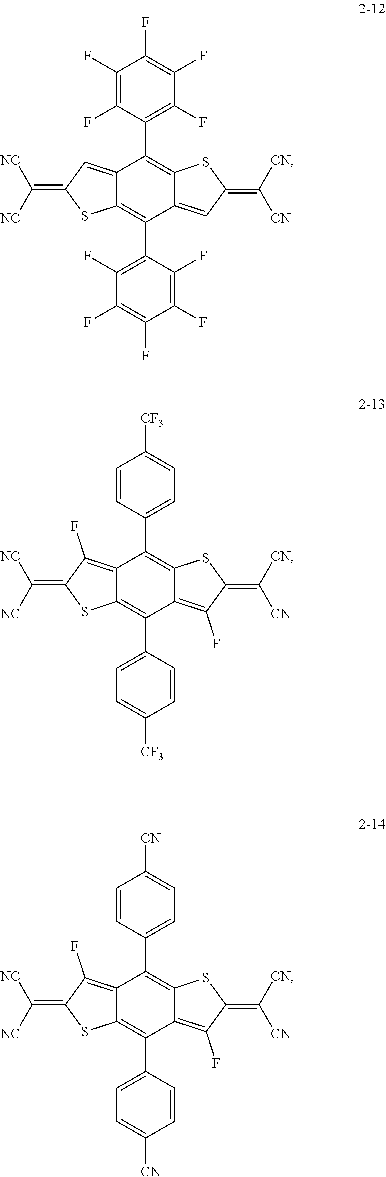 [SMILES: N#CC(C#N)=c1cc2c(-c3c(F)c(F)c(F)c(F)c3F)c3sc(=C(C#N)C#N)cc3c(-c3c(F)c(F)c(F)c(F)c3F)c2s1 ; N#CC(C#N)=c1sc2c(-c3ccc(C(F)(F)F)cc3)c3c(F)c(=C(C#N)C#N)sc3c(-c3ccc(C(F)(F)F)cc3)c2c1F ; N#CC(C#N)=c1sc2c(-c3ccc(C#N)cc3)c3c(F)c(=C(C#N)C#N)sc3c(-c3ccc(C#N)cc3)c2c1F]

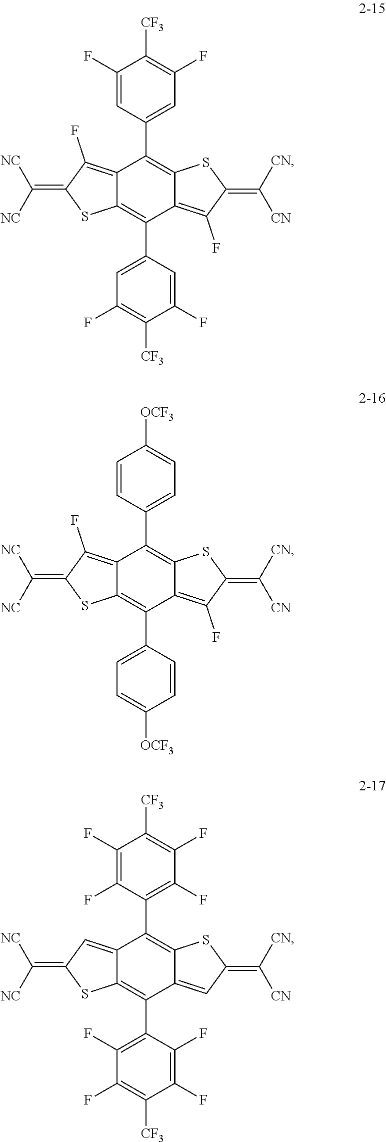 [SMILES: N#CC(C#N)=c1sc2c(-c3cc(F)c(C(F)(F)F)c(F)c3)c3c(F)c(=C(C#N)C#N)sc3c(-c3cc(F)c(C(F)(F)F)c(F)c3)c2c1F ; N#CC(C#N)=c1sc2c(-c3ccc(OC(F)(F)F)cc3)c3c(F)c(=C(C#N)C#N)sc3c(-c3ccc(OC(F)(F)F)cc3)c2c1F ; N#CC(C#N)=c1cc2c(-c3c(F)c(F)c(C(F)(F)F)c(F)c3F)c3sc(=C(C#N)C#N)cc3c(-c3c(F)c(F)c(C(F)(F)F)c(F)c3F)c2s1]

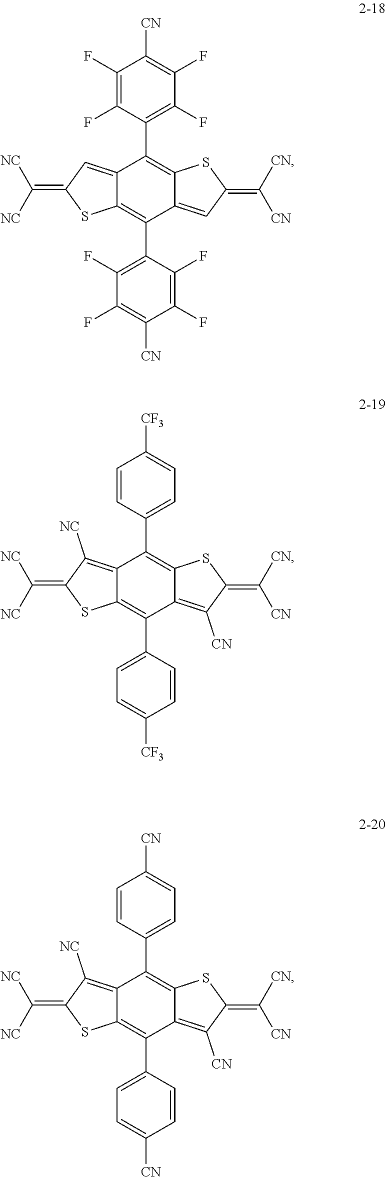 [SMILES: N#CC(C#N)=c1cc2c(-c3c(F)c(F)c(C#N)c(F)c3F)c3sc(=C(C#N)C#N)cc3c(-c3c(F)c(F)c(C#N)c(F)c3F)c2s1 ; N#CC(C#N)=c1sc2c(-c3ccc(C(F)(F)F)cc3)c3c(C#N)c(=C(C#N)C#N)sc3c(-c3ccc(C(F)(F)F)cc3)c2c1C#N ; N#CC(C#N)=c1sc2c(-c3ccc(C#N)cc3)c3c(C#N)c(=C(C#N)C#N)sc3c(-c3ccc(C#N)cc3)c2c1C#N]

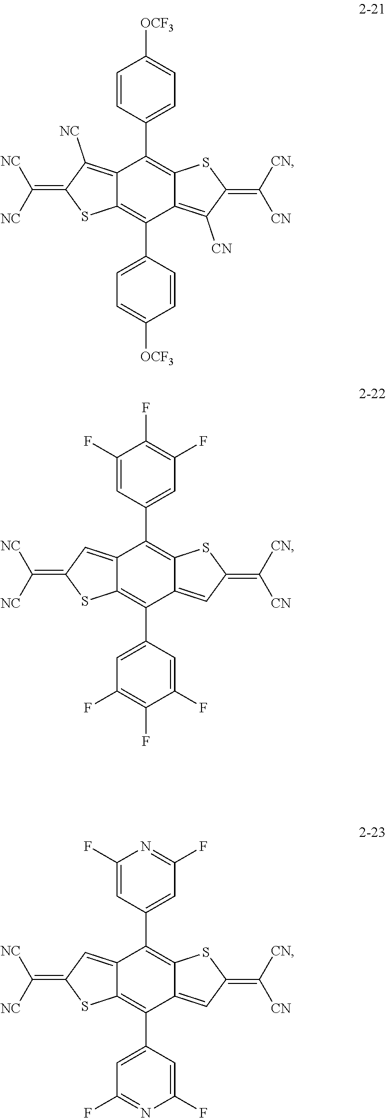 [SMILES: N#CC(C#N)=c1sc2c(-c3ccc(OC(F)(F)F)cc3)c3c(C#N)c(=C(C#N)C#N)sc3c(-c3ccc(OC(F)(F)F)cc3)c2c1C#N ; N#CC(C#N)=c1cc2c(-c3cc(F)c(F)c(F)c3)c3sc(=C(C#N)C#N)cc3c(-c3cc(F)c(F)c(F)c3)c2s1 ; N#CC(C#N)=c1cc2c(-c3cc(F)nc(F)c3)c3sc(=C(C#N)C#N)cc3c(-c3cc(F)nc(F)c3)c2s1]

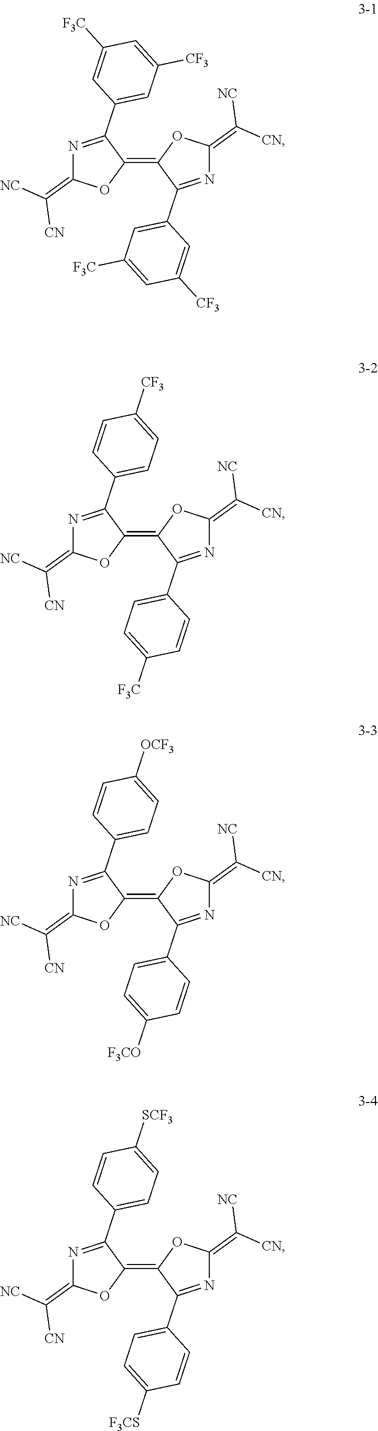

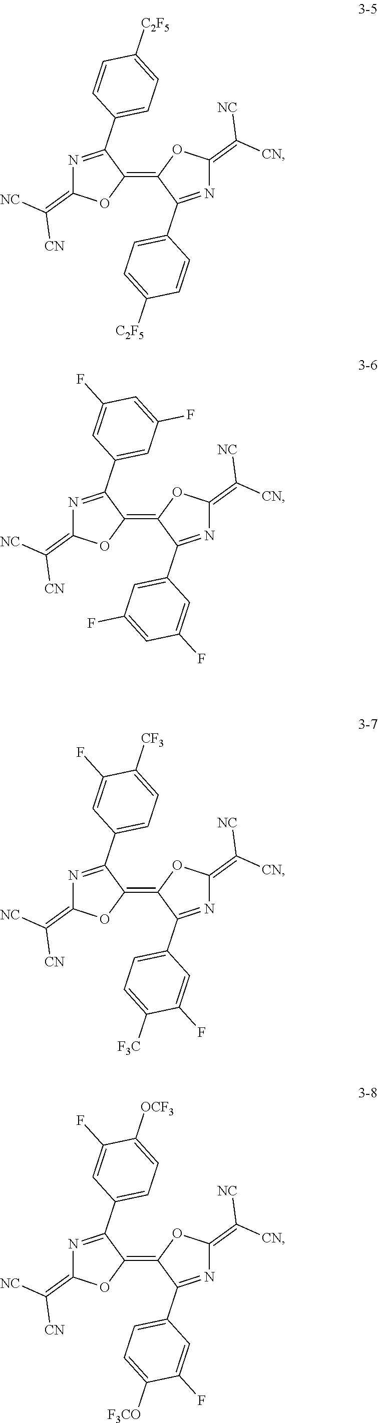

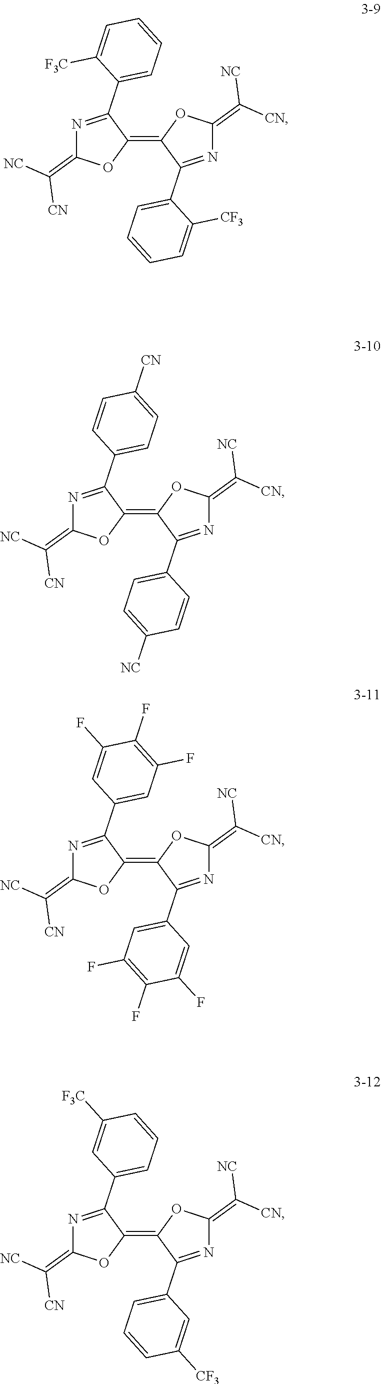

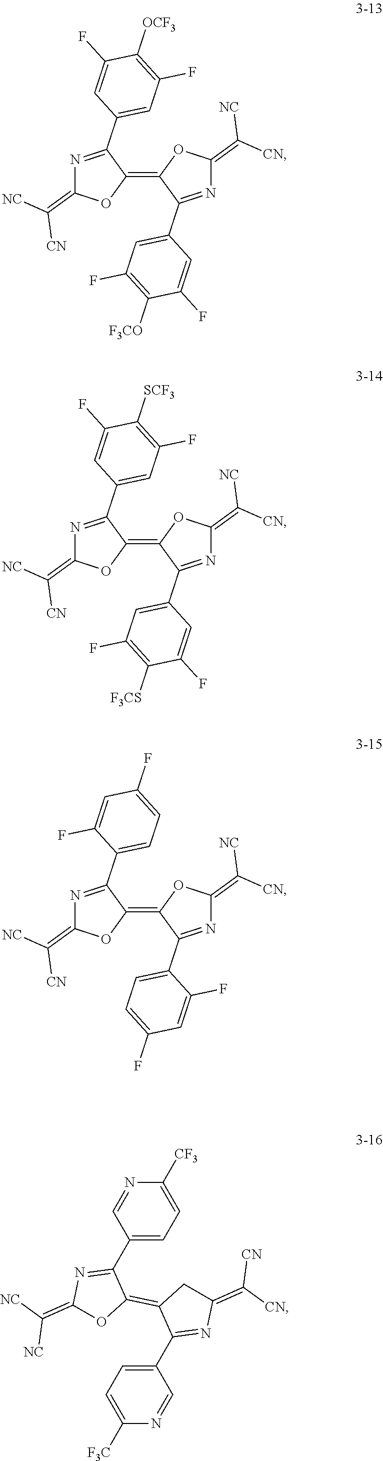

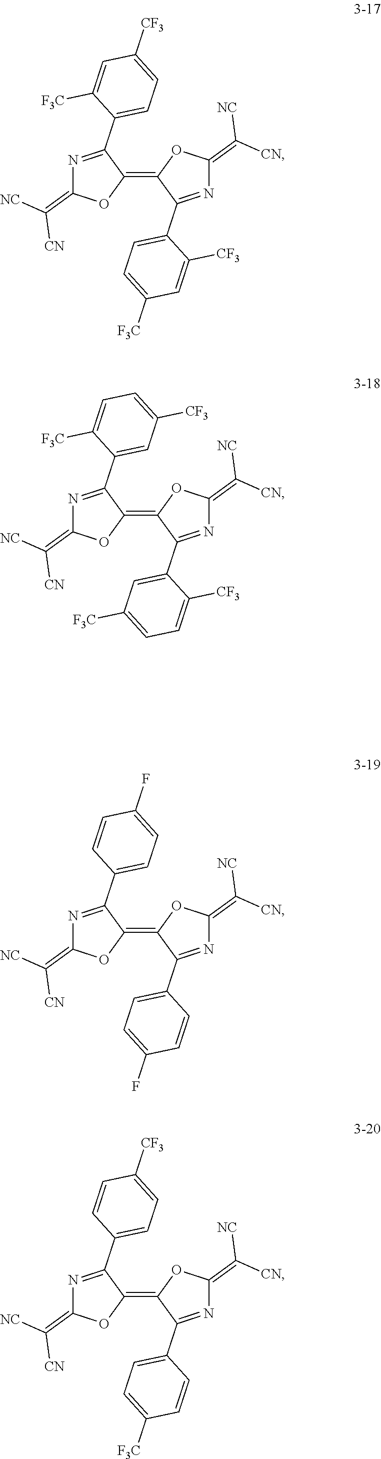 [SMILES: N#CC(C#N)=c1nc(-c2ccc(C(F)(F)F)cc2C(F)(F)F)/c(=c2\oc(=C(C#N)C#N)nc2-c2ccc(C(F)(F)F)cc2C(F)(F)F)o1 ; N#CC(C#N)=c1nc(-c2cc(C(F)(F)F)ccc2C(F)(F)F)/c(=c2\oc(=C(C#N)C#N)nc2-c2cc(C(F)(F)F)ccc2C(F)(F)F)o1 ; N#CC(C#N)=c1nc(-c2ccc(F)cc2)/c(=c2\oc(=C(C#N)C#N)nc2-c2ccc(F)cc2)o1 ; N#CC(C#N)=c1nc(-c2ccc(C(F)(F)F)cc2)/c(=c2\oc(=C(C#N)C#N)nc2-c2ccc(C(F)(F)F)cc2)o1]

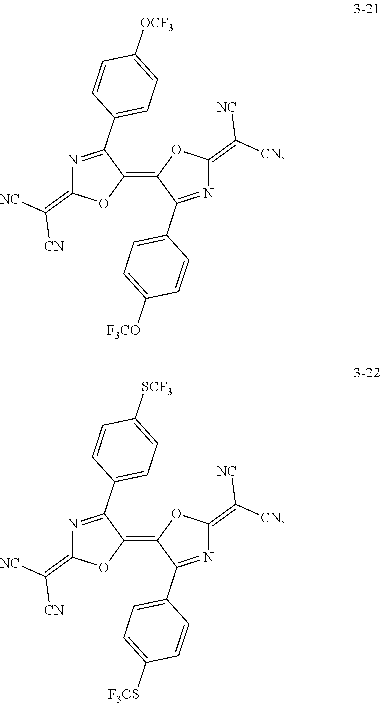

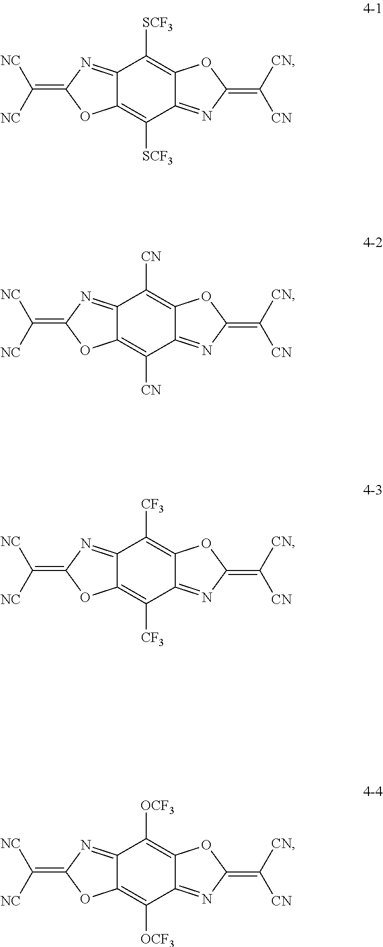

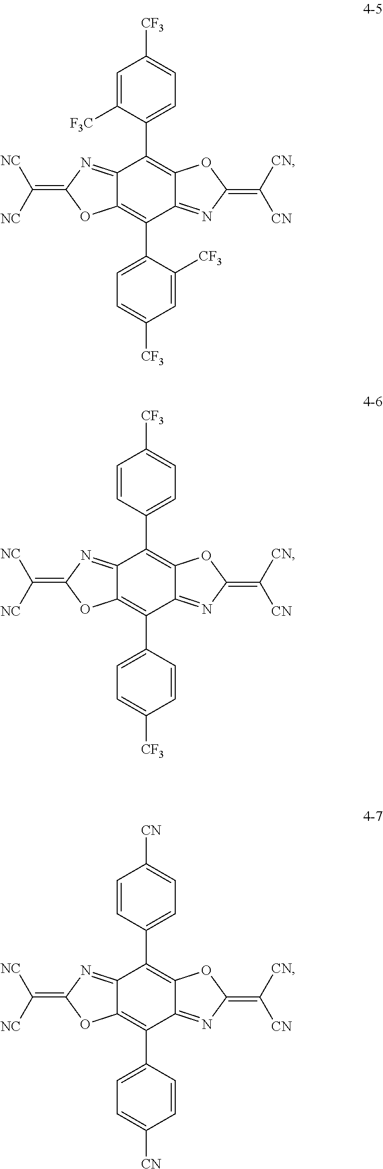 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; N#CC(C#N)=c1nc2c(-c3ccc(C(F)(F)F)cc3)c3oc(=C(C#N)C#N)nc3c(-c3ccc(C(F)(F)F)cc3)c2o1 ; N#CC(C#N)=c1nc2c(-c3ccc(C#N)cc3)c3oc(=C(C#N)C#N)nc3c(-c3ccc(C#N)cc3)c2o1]

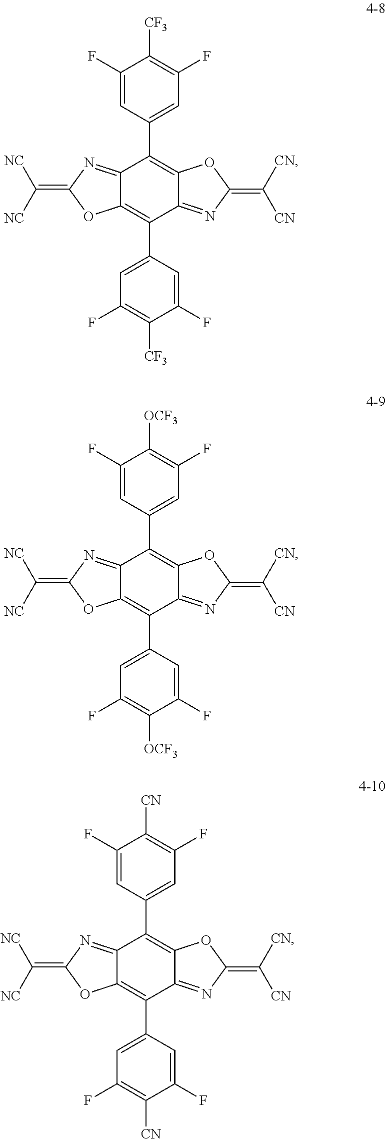 [SMILES: N#CC(C#N)=c1nc2c(-c3cc(F)c(C(F)(F)F)c(F)c3)c3oc(=C(C#N)C#N)nc3c(-c3cc(F)c(C(F)(F)F)c(F)c3)c2o1 ; N#CC(C#N)=c1nc2c(-c3cc(F)c(OC(F)(F)F)c(F)c3)c3oc(=C(C#N)C#N)nc3c(-c3cc(F)c(OC(F)(F)F)c(F)c3)c2o1 ; N#CC(C#N)=c1nc2c(-c3cc(F)c(C#N)c(F)c3)c3oc(=C(C#N)C#N)nc3c(-c3cc(F)c(C#N)c(F)c3)c2o1]

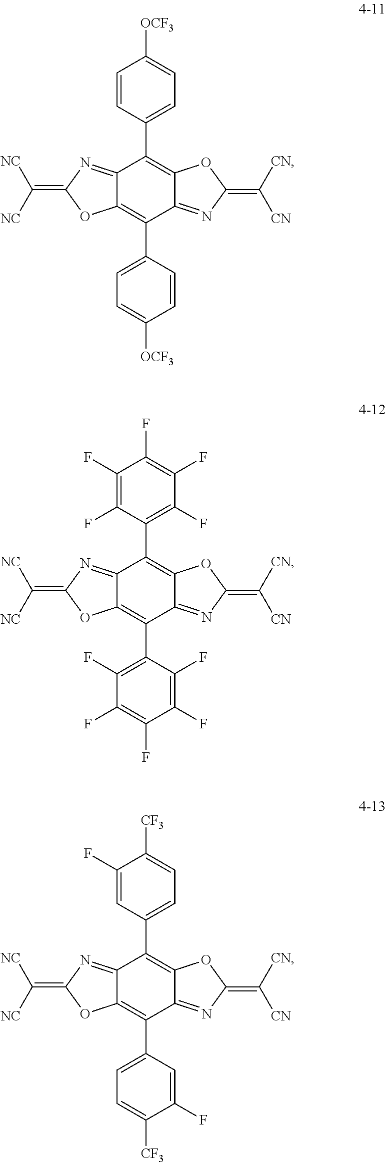 [SMILES: N#CC(C#N)=c1nc2c(-c3ccc(OC(F)(F)F)cc3)c3oc(=C(C#N)C#N)nc3c(-c3ccc(OC(F)(F)F)cc3)c2o1 ; N#CC(C#N)=c1nc2c(-c3c(F)c(F)c(F)c(F)c3F)c3oc(=C(C#N)C#N)nc3c(-c3c(F)c(F)c(F)c(F)c3F)c2o1 ; N#CC(C#N)=c1nc2c(-c3ccc(C(F)(F)F)c(F)c3)c3oc(=C(C#N)C#N)nc3c(-c3ccc(C(F)(F)F)c(F)c3)c2o1]

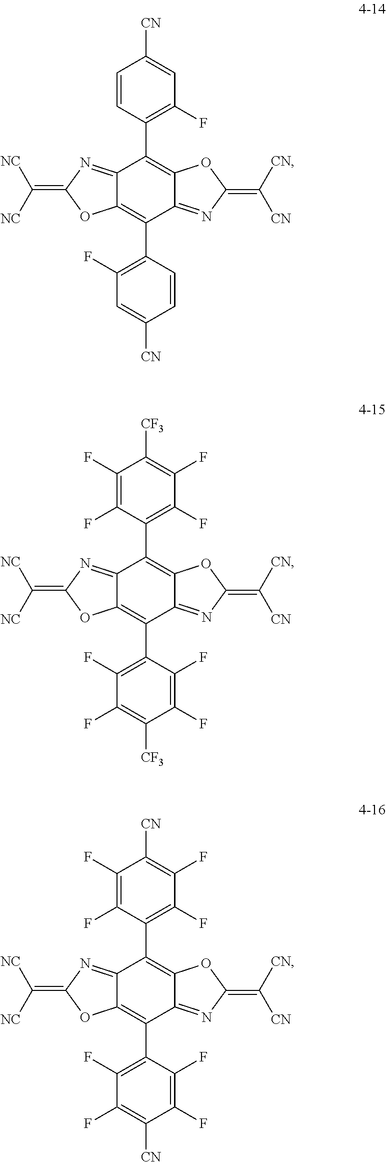 [SMILES: N#CC(C#N)=c1nc2c(-c3ccc(C#N)cc3F)c3oc(=C(C#N)C#N)nc3c(-c3ccc(C#N)cc3F)c2o1 ; N#CC(C#N)=c1nc2c(-c3c(F)c(F)c(C(F)(F)F)c(F)c3F)c3oc(=C(C#N)C#N)nc3c(-c3c(F)c(F)c(C(F)(F)F)c(F)c3F)c2o1 ; N#CC(C#N)=c1nc2c(-c3c(F)c(F)c(C#N)c(F)c3F)c3oc(=C(C#N)C#N)nc3c(-c3c(F)c(F)c(C#N)c(F)c3F)c2o1]

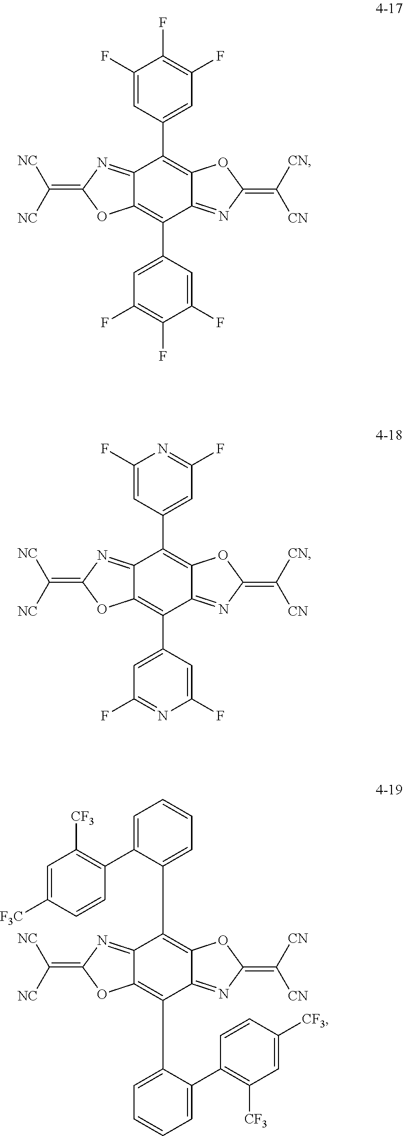 [SMILES: N#CC(C#N)=c1nc2c(-c3cc(F)c(F)c(F)c3)c3oc(=C(C#N)C#N)nc3c(-c3cc(F)c(F)c(F)c3)c2o1 ; N#CC(C#N)=c1nc2c(-c3cc(F)nc(F)c3)c3oc(=C(C#N)C#N)nc3c(-c3cc(F)nc(F)c3)c2o1 ; N#CC(C#N)=c1nc2c(-c3ccccc3-c3ccc(C(F)(F)F)cc3C(F)(F)F)c3oc(=C(C#N)C#N)nc3c(-c3ccccc3-c3ccc(C(F)(F)F)cc3C(F)(F)F)c2o1]

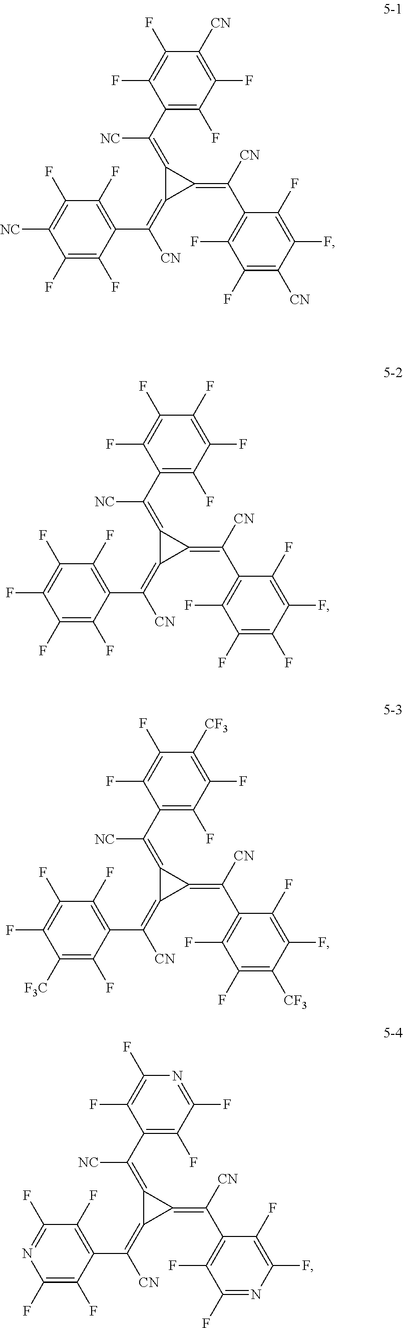 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(=C1C(=C(C#N)c2c(F)c(F)c(F)c(F)c2F)C1=C(C#N)c1c(F)c(F)c(F)c(F)c1F)c1c(F)c(F)c(F)c(F)c1F ; N#C/C(=C1/C(=C(\C#N)c2c(F)c(F)c(F)c(C(F)(F)F)c2F)/C1=C(\C#N)c1c(F)c(F)c(C(F)(F)F)c(F)c1F)c1c(F)c(F)c(C(F)(F)F)c(F)c1F ; N#CC(=C1C(=C(C#N)c2c(F)c(F)nc(F)c2F)C1=C(C#N)c1c(F)c(F)nc(F)c1F)c1c(F)c(F)nc(F)c1F]

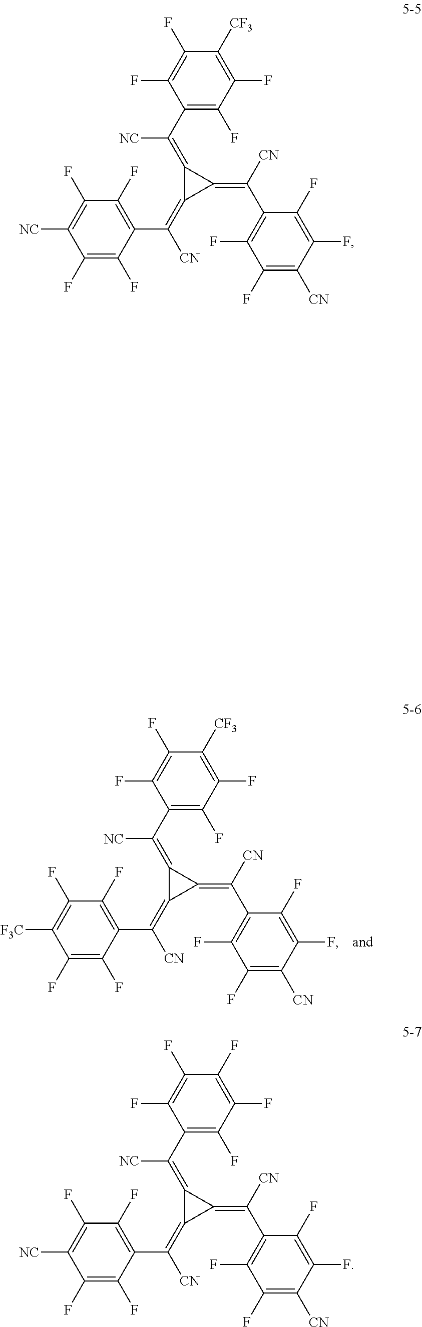

According to an embodiment of the present disclosure, the first organic material and/or the second organic material are selected from the group consisting of the following compounds: a compound having a triarylamine unit, a spirobifluorene compound, a pentacene compound, an oligothiophene compound, an oligophenyl compound, an oligophenylenevinylene compound, an oligofluorene compound, a porphyrin complex and a metallic phthalocyanine complex.

According to an embodiment of the present disclosure, the first organic material, the second organic material and the third organic material are all hole transporting materials.

According to an embodiment of the present disclosure, the first organic material and/or the second organic material comprise any one or more chemical structural units selected from the group consisting of triarylamine, carbazole, fluorene, spirobifluorene, thiophene, furan, phenyl, oligophenylenevinylene, oligofluorene, and combinations thereof.

According to an embodiment of the present disclosure, the first organic material and/or the second organic material comprise a monotriarylamine structural unit or a bistriarylamine structural unit.

According to an embodiment of the present disclosure, the first organic material and/or the second organic material comprise any one or more chemical structural units selected from the group consisting of: a monotriarylamine-carbazole structural unit, a monotriarylamine-thiophene structural unit, a monotriarylamine-furan structural unit, a monotriarylamine-fluorene structural unit, a bistriarylamine-carbazole structural unit, a bistriarylamine-thiophene structural unit, a bistriarylamine-furan structural unit, and a bistriarylamine-fluorene structural unit.

According to an embodiment of the present disclosure, the first organic material and/or the second organic material are a monotriarylamine compound or a bistriarylamine compound.

According to an embodiment of the present disclosure, the first organic material and/or the second organic material are selected from a monotriarylamine-carbazole compound, a monotriarylamine-thiophene compound, a monotriarylamine-furan compound, a monotriarylamine-fluorene compound, a bistriarylamine-carbazole compound, a bistriarylamine-thiophene compound, a bistriarylamine-furan compound, or a bistriarylamine-fluorene compound.

According to an embodiment of the present disclosure, the first organic material and/or the second organic material comprising a monotriarylamine structural unit have a structure represented by Formula 20 or Formula 21:

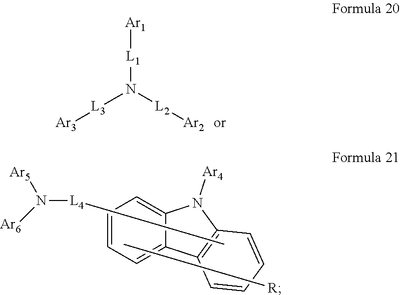

wherein Ar₁, Ar₂, Ar₃, Ar₄, Ar₅, and Ar₆ are, at each occurrence identically or differently, selected from substituted or unsubstituted aryl having 6 to 30 carbon atoms or substituted or unsubstituted heteroaryl having 3 to 30 carbon atoms; and the structures of Ar₁, Ar₂, Ar₃, Ar₄, Ar₅, and Ar₆ do not comprise carbazole;
L₁, L₂, L₃, and L₄ are, at each occurrence identically or differently, selected from a single bond, substituted or unsubstituted arylene having 6 to 30 carbon atoms, substituted or unsubstituted heteroarylene having 3 to 30 carbon atoms, or a combination thereof; and the structures of L₁, L₂, L₃, and L₄ do not comprise carbazole;
R represents, at each occurrence identically or differently, mono-substitution, multiple substitutions, or non-substitution;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and the R do not comprise carbazole;
adjacent substituents can be optionally joined to form a ring.

According to an embodiment of the present disclosure, Ar₁, Ar₂, Ar₃, Ar₄, Ar₅, and Ar₆ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted dibenzofuryl, substituted or unsubstituted dibenzothienyl, substituted or unsubstituted dibenzoselenophenyl, substituted or unsubstituted phenanthryl, substituted or unsubstituted triphenylenyl, substituted or unsubstituted pyridyl, substituted or unsubstituted anthryl, substituted or unsubstituted pyrenyl, substituted or unsubstituted fluorenyl, or a combination thereof.

According to an embodiment of the present disclosure, L₁, L₂, L₃, and L₄ are, at each occurrence identically or differently, selected from a single bond, substituted or unsubstituted phenylene, substituted or unsubstituted biphenylene, substituted or unsubstituted terphenylene, substituted or unsubstituted naphthylene, substituted or unsubstituted dibenzofurylene, substituted or unsubstituted dibenzothienylene, substituted or unsubstituted dibenzoselenophenylene, substituted or unsubstituted phenanthrylene, substituted or unsubstituted triphenylenylene, substituted or unsubstituted pyridylene, substituted or unsubstituted anthrylene, substituted or unsubstituted pyrenylene, substituted or unsubstituted fluorenylene, or a combination thereof.

According to an embodiment of the present disclosure, the first organic material and/or the second organic material having a bistriarylamine structural unit has a structure represented by Formula 22:

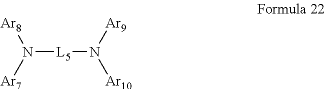

wherein Ar₇, Ar₈, Ar₉ and Ar₁₀ are selected from substituted or unsubstituted aryl having 6 to 30 carbon atoms or substituted or unsubstituted heteroaryl having 3 to 30 carbon atoms;
adjacent substituents Ar₇ and Ar₈ are not joined to form a ring or adjacent substituents Ar₉ and Ar₁₀ are not joined to form a ring;
L₅ is selected from substituted or unsubstituted arylene having 6 to 30 carbon atoms or substituted or unsubstituted heteroarylene having 3 to 30 carbon atoms.

According to an embodiment of the present disclosure, Ar₇, Ar₅, Ar₉ and Ar₁₀ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted carbazolyl, substituted or unsubstituted dibenzofuryl, substituted or unsubstituted dibenzothienyl, substituted or unsubstituted dibenzoselenophenyl, substituted or unsubstituted phenanthryl, substituted or unsubstituted triphenylenyl, substituted or unsubstituted pyridyl, substituted or unsubstituted anthryl, substituted or unsubstituted pyrenyl, substituted or unsubstituted fluorenyl, or combinations thereof; wherein adjacent substituents Ar₇ and Ar₈ are not joined to form a ring or adjacent substituents Ar₉ and Ar₁₀ are not joined to form a ring.

According to an embodiment of the present disclosure, L₅ is selected from a single bond, substituted or unsubstituted phenylene, substituted or unsubstituted biphenylene, substituted or unsubstituted terphenylene, substituted or unsubstituted naphthylene, substituted or unsubstituted carbazolylene, substituted or unsubstituted dibenzofurylene, substituted or unsubstituted dibenzothienylene, substituted or unsubstituted dibenzoselenophenylene, substituted or unsubstituted phenanthrylene, substituted or unsubstituted triphenylenylene, substituted or unsubstituted pyridylene, substituted or unsubstituted anthrylene, substituted or unsubstituted pyrenylene, substituted or unsubstituted fluorenylene, or combinations thereof.

According to an embodiment of the present disclosure, the first organic material and/or the second organic material include one or more chemical structural units selected from the group consisting of: triarylamine, carbazole, fluorene, spirobifluorene, thiophene, furan, phenyl, oligophenylenevinylene, oligofluorene, and combinations thereof.

According to an embodiment of the present disclosure, the first organic material and/or the second organic material are selected from the group consisting of, but not limited to, the following structures:

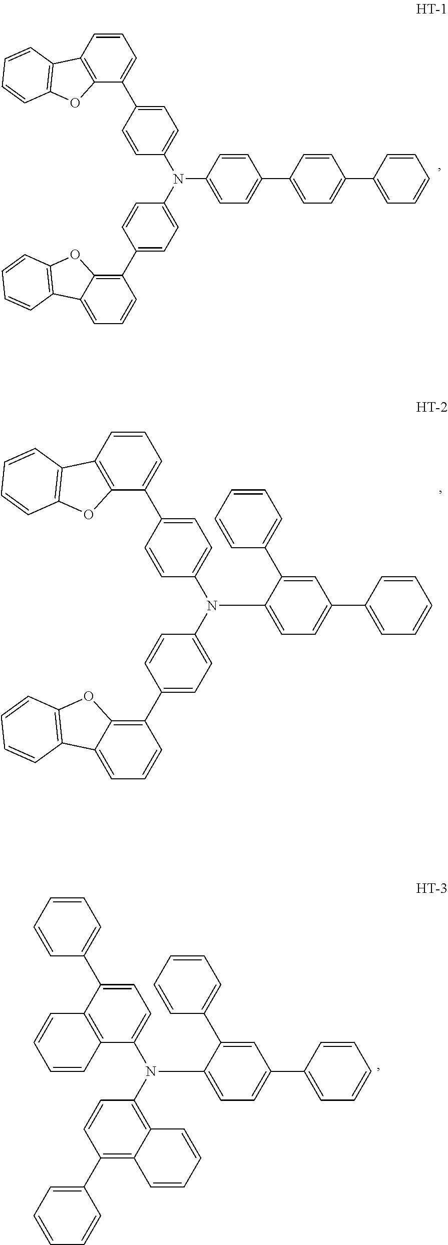 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(N(c3ccc(-c4cccc5c4oc4ccccc45)cc3)c3ccc(-c4cccc5c4oc4ccccc45)cc3)c(-c3ccccc3)c2)cc1 ; c1ccc(-c2ccc(N(c3ccc(-c4ccccc4)c4ccccc34)c3ccc(-c4ccccc4)c4ccccc34)c(-c3ccccc3)c2)cc1]

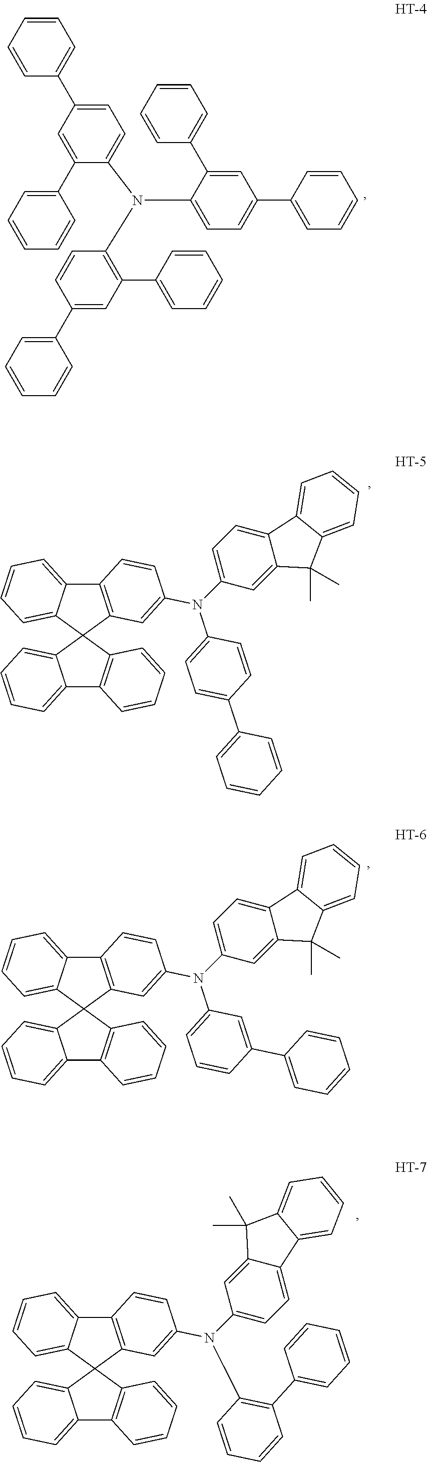 [SMILES: c1ccc(-c2ccc(N(c3ccc(-c4ccccc4)cc3-c3ccccc3)c3ccc(-c4ccccc4)cc3-c3ccccc3)c(-c3ccccc3)c2)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3cccc(-c4ccccc4)c3)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccccc3-c3ccccc3)cc21]

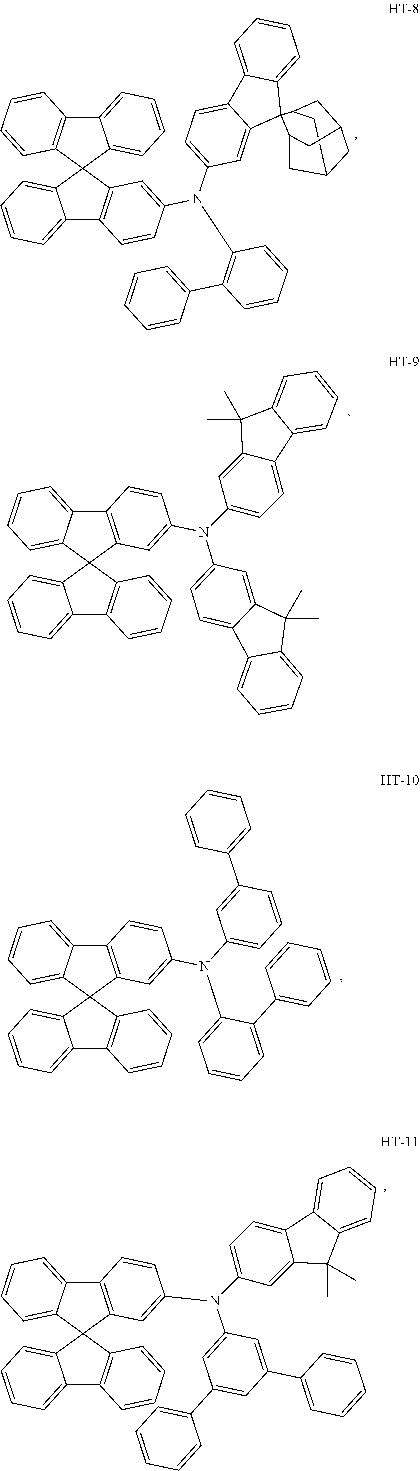 [SMILES: c1ccc(-c2ccccc2N(c2ccc3c(c2)C2(c4ccccc4-c4ccccc42)c2ccccc2-3)c2ccc3c(c2)C2(c4ccccc4-3)C3CC4CC(C3)CC2C4)cc1 ; CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21 ; c1ccc(-c2cccc(N(c3ccc4c(c3)C3(c5ccccc5-c5ccccc53)c3ccccc3-4)c3ccccc3-c3ccccc3)c2)cc1 ; CC1(C)c2ccccc2-c2ccc(N(c3cc(-c4ccccc4)cc(-c4ccccc4)c3)c3ccc4c(c3)C3(c5ccccc5-c5ccccc53)c3ccccc3-4)cc21]

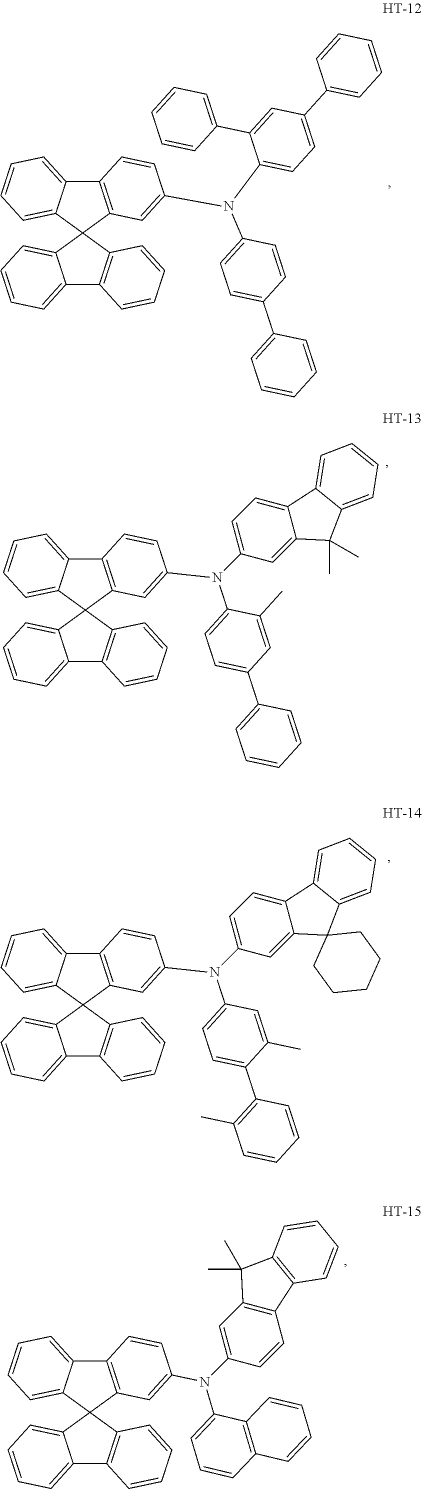 [SMILES: c1ccc(-c2ccc(N(c3ccc4c(c3)C3(c5ccccc5-c5ccccc53)c3ccccc3-4)c3ccc(-c4ccccc4)cc3-c3ccccc3)cc2)cc1 ; Cc1cc(-c2ccccc2)ccc1N(c1ccc2c(c1)C(C)(C)c1ccccc1-2)c1ccc2c(c1)C1(c3ccccc3-c3ccccc31)c1ccccc1-2 ; Cc1ccccc1-c1ccc(N(c2ccc3c(c2)C2(CCCCC2)c2ccccc2-3)c2ccc3c(c2)C2(c4ccccc4-c4ccccc42)c2ccccc2-3)cc1C ; CC1(C)c2ccccc2-c2ccc(N(c3ccc4c(c3)C3(c5ccccc5-c5ccccc53)c3ccccc3-4)c3cccc4ccccc34)cc21]

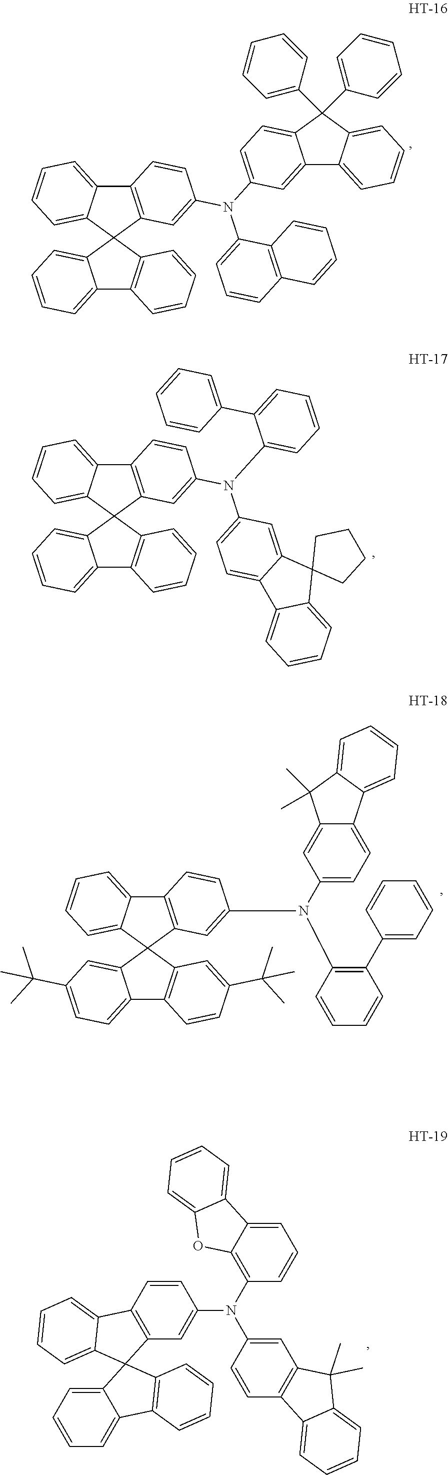 [SMILES: c1ccc(C2(c3ccccc3)c3ccccc3-c3cc(N(c4ccc5c(c4)C4(c6ccccc6-c6ccccc64)c4ccccc4-5)c4cccc5ccccc45)ccc32)cc1 ; c1ccc(-c2ccccc2N(c2ccc3c(c2)C2(CCCC2)c2ccccc2-3)c2ccc3c(c2)C2(c4ccccc4-c4ccccc42)c2ccccc2-3)cc1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; CC1(C)c2ccccc2-c2ccc(N(c3ccc4c(c3)C3(c5ccccc5-c5ccccc53)c3ccccc3-4)c3cccc4c3oc3ccccc34)cc21]

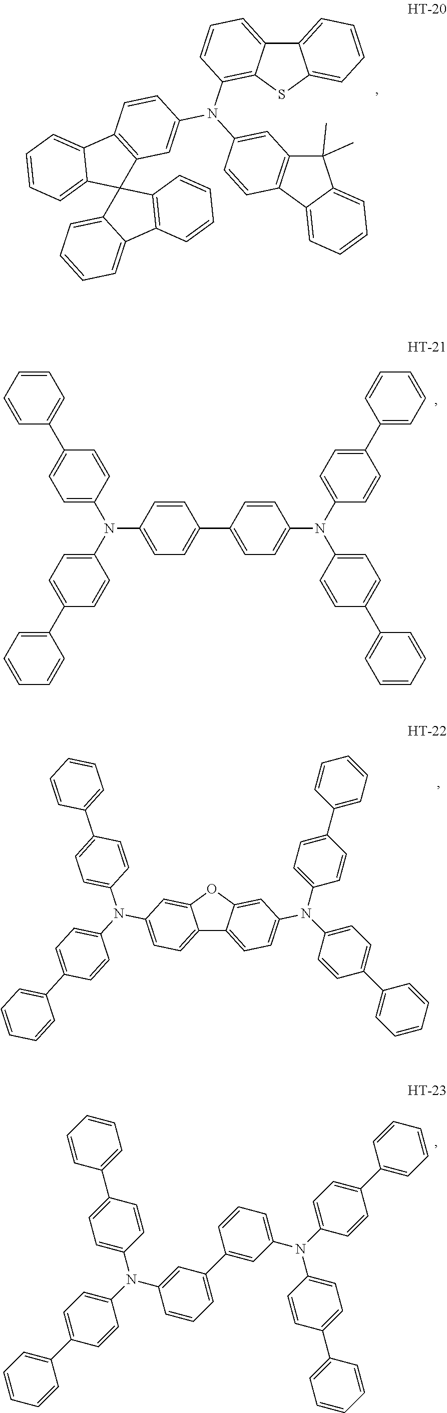 [SMILES: CC1(C)c2ccccc2-c2ccc(N(c3ccc4c(c3)C3(c5ccccc5-c5ccccc53)c3ccccc3-4)c3cccc4c3sc3ccccc34)cc21 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(N(c3ccc(-c4ccccc4)cc3)c3ccc4c(c3)oc3cc(N(c5ccc(-c6ccccc6)cc5)c5ccc(-c6ccccc6)cc5)ccc34)cc2)cc1 ; c1ccc(-c2ccc(N(c3ccc(-c4ccccc4)cc3)c3cccc(-c4cccc(N(c5ccc(-c6ccccc6)cc5)c5ccc(-c6ccccc6)cc5)c4)c3)cc2)cc1]

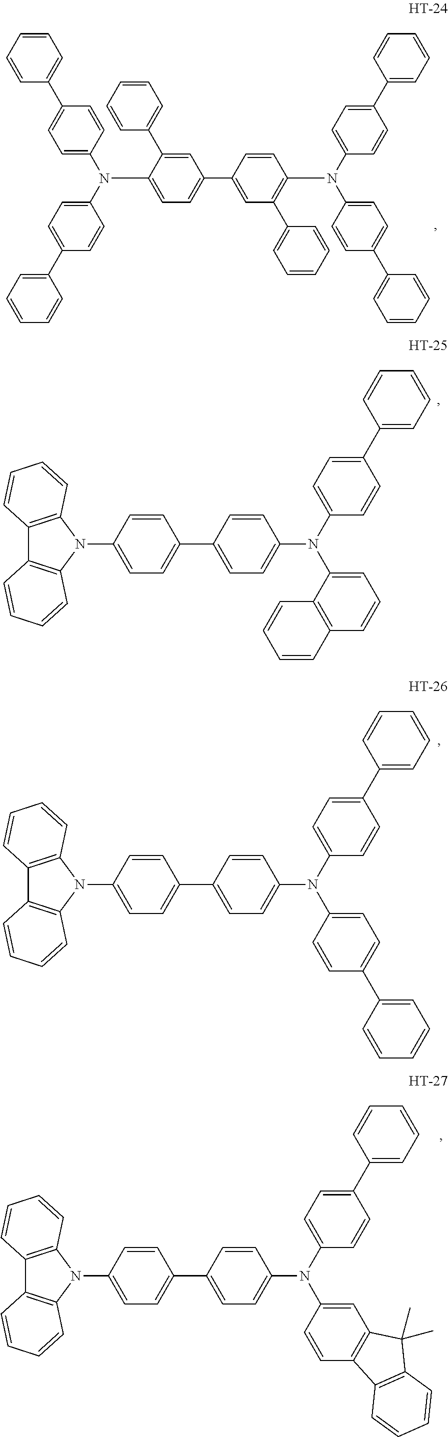 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)c(-c5ccccc5)c4)cc3-c3ccccc3)cc2)cc1 ; c1ccc(-c2ccc(N(c3ccc(-c4ccc(-n5c6ccccc6c6ccccc65)cc4)cc3)c3cccc4ccccc34)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc(-c4ccc(-n5c6ccccc6c6ccccc65)cc4)cc3)cc21]

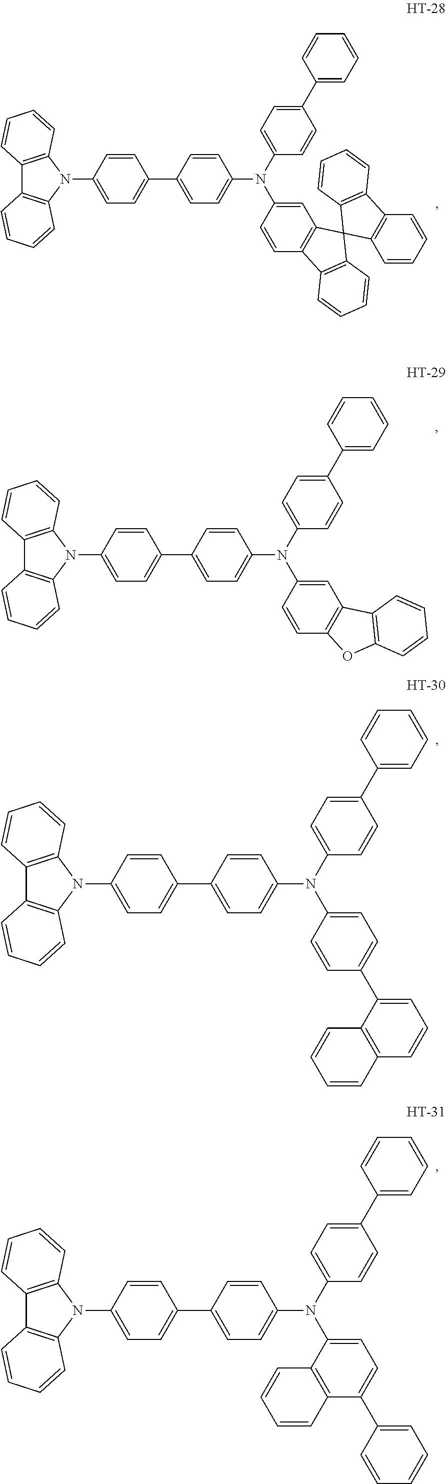 [SMILES: c1ccc(-c2ccc(N(c3ccc(-c4ccc(-n5c6ccccc6c6ccccc65)cc4)cc3)c3ccc4c(c3)C3(c5ccccc5-c5ccccc53)c3ccccc3-4)cc2)cc1 ; c1ccc(-c2ccc(N(c3ccc(-c4ccc(-n5c6ccccc6c6ccccc65)cc4)cc3)c3ccc4oc5ccccc5c4c3)cc2)cc1 ; c1ccc(-c2ccc(N(c3ccc(-c4ccc(-n5c6ccccc6c6ccccc65)cc4)cc3)c3ccc(-c4cccc5ccccc45)cc3)cc2)cc1 ; c1ccc(-c2ccc(N(c3ccc(-c4ccc(-n5c6ccccc6c6ccccc65)cc4)cc3)c3ccc(-c4ccccc4)c4ccccc34)cc2)cc1]

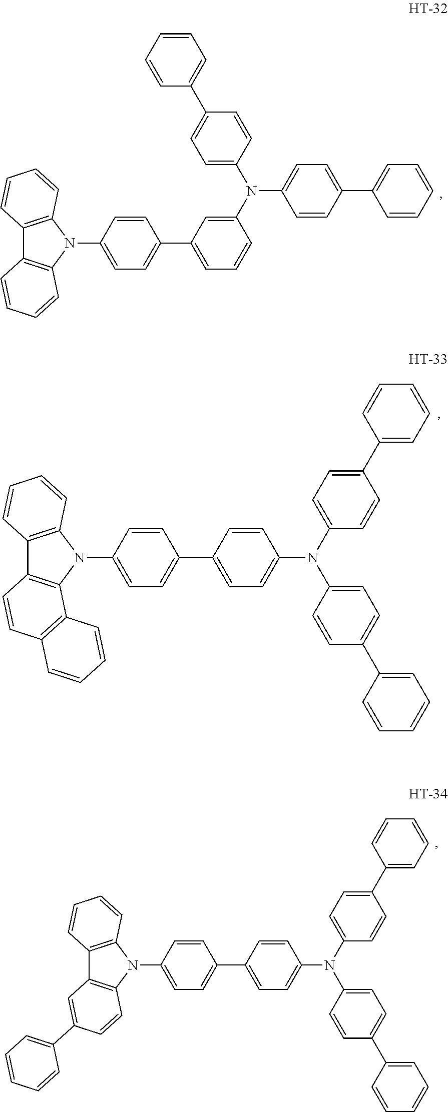 [SMILES: c1ccc(-c2ccc(N(c3ccc(-c4ccccc4)cc3)c3cccc(-c4ccc(-n5c6ccccc6c6ccccc65)cc4)c3)cc2)cc1 ; c1ccc(-c2ccc(N(c3ccc(-c4ccccc4)cc3)c3ccc(-c4ccc(-n5c6ccccc6c6ccc7ccccc7c65)cc4)cc3)cc2)cc1 ; c1ccc(-c2ccc(N(c3ccc(-c4ccccc4)cc3)c3ccc(-c4ccc(-n5c6ccccc6c6cc(-c7ccccc7)ccc65)cc4)cc3)cc2)cc1]

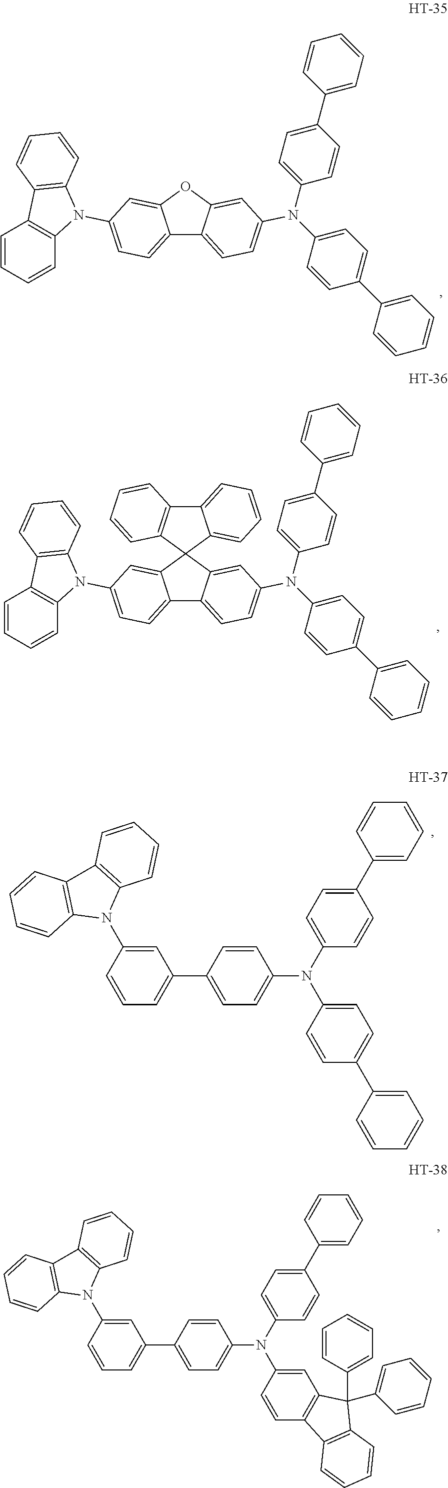 [SMILES: c1ccc(-c2ccc(N(c3ccc(-c4ccccc4)cc3)c3ccc4c(c3)oc3cc(-n5c6ccccc6c6ccccc65)ccc34)cc2)cc1 ; c1ccc(-c2ccc(N(c3ccc(-c4ccccc4)cc3)c3ccc4c(c3)C3(c5ccccc5-c5ccccc53)c3cc(-n5c6ccccc6c6ccccc65)ccc3-4)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(N(c3ccc(-c4cccc(-n5c6ccccc6c6ccccc65)c4)cc3)c3ccc4c(c3)C(c3ccccc3)(c3ccccc3)c3ccccc3-4)cc2)cc1]

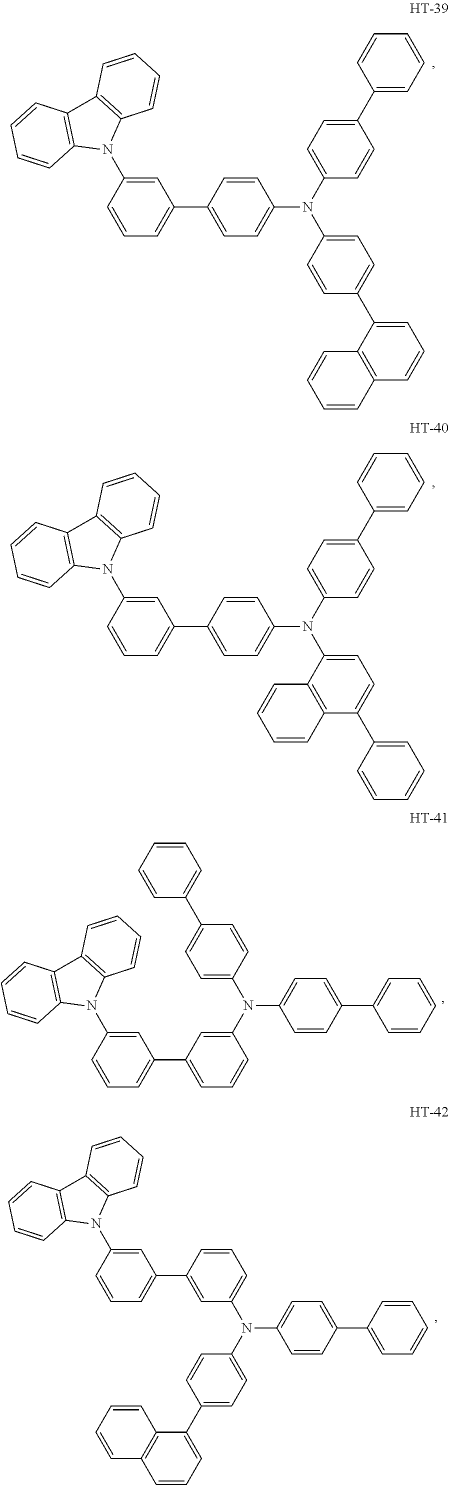 [SMILES: c1ccc(-c2ccc(N(c3ccc(-c4cccc(-n5c6ccccc6c6ccccc65)c4)cc3)c3ccc(-c4cccc5ccccc45)cc3)cc2)cc1 ; c1ccc(-c2ccc(N(c3ccc(-c4cccc(-n5c6ccccc6c6ccccc65)c4)cc3)c3ccc(-c4ccccc4)c4ccccc34)cc2)cc1 ; c1ccc(-c2ccc(N(c3ccc(-c4ccccc4)cc3)c3cccc(-c4cccc(-n5c6ccccc6c6ccccc65)c4)c3)cc2)cc1 ; c1ccc(-c2ccc(N(c3ccc(-c4cccc5ccccc45)cc3)c3cccc(-c4cccc(-n5c6ccccc6c6ccccc65)c4)c3)cc2)cc1]

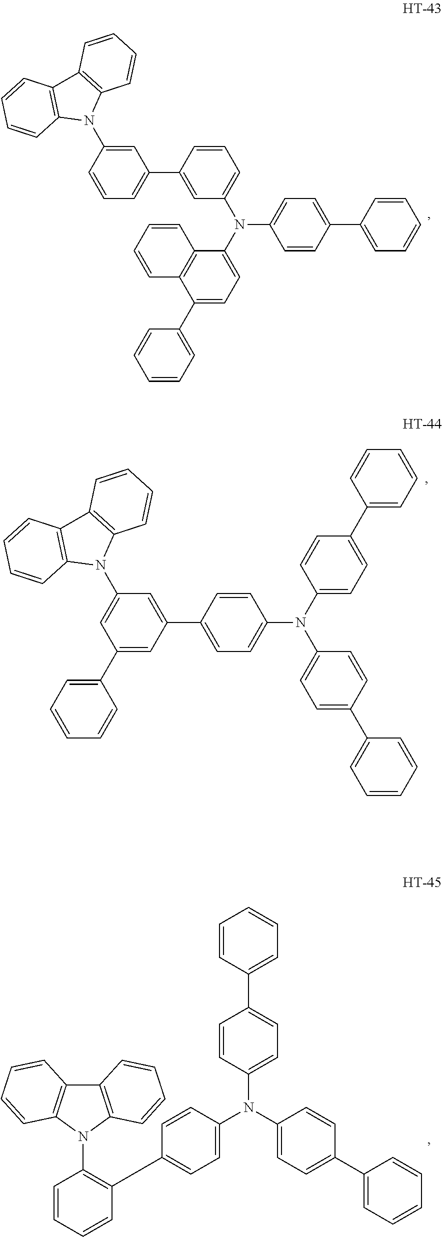 [SMILES: c1ccc(-c2ccc(N(c3cccc(-c4cccc(-n5c6ccccc6c6ccccc65)c4)c3)c3ccc(-c4ccccc4)c4ccccc34)cc2)cc1 ; c1ccc(-c2ccc(N(c3ccc(-c4ccccc4)cc3)c3ccc(-c4cc(-c5ccccc5)cc(-n5c6ccccc6c6ccccc65)c4)cc3)cc2)cc1 ; c1ccc(-c2ccc(N(c3ccc(-c4ccccc4)cc3)c3ccc(-c4ccccc4-n4c5ccccc5c5ccccc54)cc3)cc2)cc1]

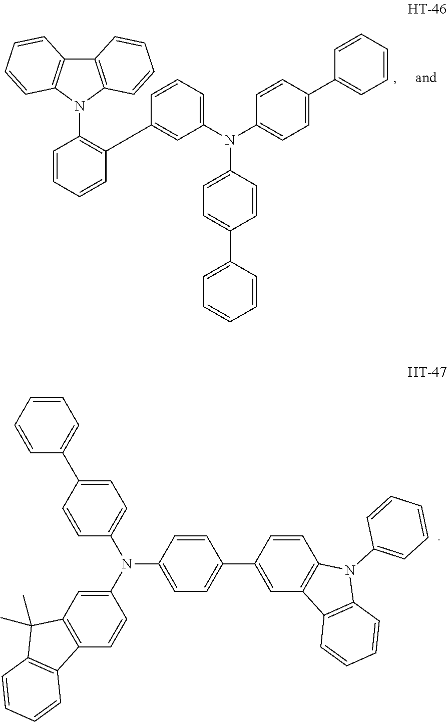 [SMILES: c1ccc(-c2ccc(N(c3ccc(-c4ccccc4)cc3)c3cccc(-c4ccccc4-n4c5ccccc5c5ccccc54)c3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

In terms of device structures, OLEDs can be classified into conventional OLEDs having a single-layer structure and OLEDs having a tandem structure (also called a stacked structure). The conventional single-layer OLED includes only one emissive unit between the cathode and the anode, while the tandem OLED includes multiple stacked emissive units. One emissive unit generally includes at least one emissive layer, one hole transporting layer and one electron transporting layer. On this basis, the emissive unit may further include a hole injection layer, an electron injection layer, a hole blocking layer and an electron blocking layer. It is to be noted that although the conventional single-layer OLED has only one emissive unit, this emissive unit may include multiple emissive layers, for example, the emissive unit may include one yellow emissive layer and one blue emissive layer. However, each emissive unit includes only one pair of a hole transporting layer and an electron transporting layer. The tandem OLED includes at least two emissive units, that is, the tandem OLED includes at least two pairs of hole transporting layers and electron transporting layers. Here, multiple emissive units are arranged in a vertically-stacked physical format to achieve a series circuit. Therefore, this type of OLED is referred to as a tandem OLED (in terms of the circuit connection) or a stacked OLED (in terms of the physical format). Under the same brightness, the tandem OLED requires a smaller current density than the conventional single-layer OLED, thereby prolonging a lifetime. On the contrary, at a constant current density, the tandem OLED provides higher brightness than the conventional single-layer OLED, with an increase in voltage. Adjacent emissive units of the tandem OLED are connected by a charge generation layer, and the quality of the charge generation layer directly affects parameters of the tandem OLED, such as voltage, lifetime, and efficiency. Therefore, the charge generation layer is required to be able to effectively generate holes and electrons and smoothly inject the holes and the electrons to corresponding emissive units and is also required to have greater transmittance in a visible light range and meanwhile have stable performance and be easy to prepare.

Herein, the LUMO energy level and the HOMO energy level of the compound are measured by cyclic voltammetry. The measurement is conducted using an electrochemical workstation model No. CorrTest CS120 produced by WUHAN CORRTEST INSTRUMENTS CORP., LTD and using a three-electrode working system where a platinum disk electrode serves as a working electrode, a Ag/AgNO₃ electrode serves as a reference electrode, and a platinum wire electrode serves as an auxiliary electrode. With anhydrous DCM as a solvent and 0.1 mol/L tetrabutylammonium hexafluorophosphate as a supporting electrolyte, a target compound is prepared into a solution of 10⁻³ mol/L, and nitrogen is introduced into the solution for 10 min for oxygen removal before the measurement. The parameters of the instrument are set as follows: a scan rate of 100 mV/s, a potential interval of 0.5 mV, and a test window of 1 V to −0.5 V. The LUMO energy levels of some p-type dopants and the HOMO energy levels of organic materials in the present application are recorded in Table 1 below, which were measured according to the above measurement method. The LUMO energy levels of the p-type dopants are all less than −4.35 eV.

TABLE 1
LUMO energy levels of some p-type dopants
and HOMO energy levels of organic materials

| Compound | LUMO (eV) | Compound | HOMO (eV) |
|---|---|---|---|
| 5-1 | −5.04 | HT-1 | −5.35 |
| 3-1 | −4.91 | HT-7 | −5.14 |
| 1-2 | −4.63 | HT-18 | −5.13 |
| 4-5 | −5.17 | HT-21 | −5.09 |
| 4-19 | −5.12 | HT-37 | −5.26 |
| 2-5 | −4.54 | HT-44 | −5.27 |
| 3-2 | −4.81 | HT-47 | −5.10 |
| 4-6 | −5.13 | | |
| 4-11 | −5.11 | | |

The HOMO energy level of the commonly used HTM is generally less than −4.5 eV. The present application adopts the p-type dopant whose LUMO energy level is less than −4.35 eV to reduce the energy level difference with the HOMO of the HTM, ensuring hole injection and stabilizing the device voltage. When the p-type dopant whose LUMO energy level is less than −4.35 eV is applied to the device with a specific structure of the present application, the comprehensive performance of the device can be further improved.

The materials described herein as useful for a particular layer in an organic light-emitting device may be used in combination with a variety of other materials present in the device. For example, compounds disclosed herein may be used in combination with a wide variety of emissive dopants, hosts, transporting layers, blocking layers, injection layers, electrodes and other layers that may be present. The combination of these materials is described in detail in paragraphs 0080-0101 of U.S. Pat. App. Pub. No. 20150349273, which is incorporated by reference herein in its entirety. The materials described or referred to in the disclosure are non-limiting examples of materials that may be useful in combination with the compounds disclosed herein, and those skilled in the art can readily consult the literature to identify other materials that may be useful in combination.

In the embodiments of the device, the characteristics of the device were also tested using conventional equipment in the art (including, but not limited to, an evaporator produced by ANGSTROM ENGINEERING, an optical testing system produced by SUZHOU FATAR, a lifetime testing system produced by SUZHOU FATAR, and an ellipsometer produced by BEIJING ELLITOP, etc.) by methods well-known to the persons skilled in the art. As the persons skilled in the art are aware of the above-mentioned equipment use, test methods and other related contents, the inherent data of the sample can be obtained with certainty and without influence, so the above related contents are not further described in the present disclosure.

### EXAMPLE

The working principle of the organic electroluminescent device is specifically described below through several examples. Apparently, the following examples are only for the purpose of illustration and are not intended to limit the scope of the present disclosure. Based on the following examples, the persons skilled in the art can obtain other examples of the present disclosure by conducting improvements on these examples.

### Example 1-1

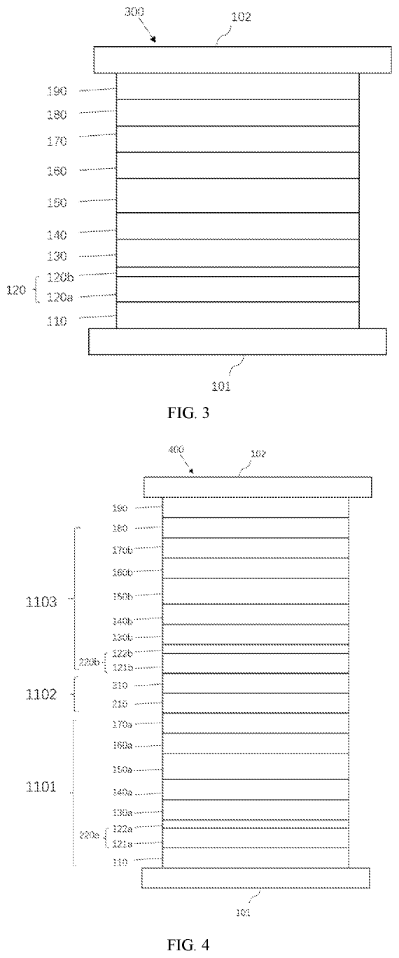

An organic electroluminescent device 300 was prepared, as shown in FIG. 3 (wherein the hole blocking layer 160 is omitted in this example and the persons skilled in the art may add a hole blocking layer as needed). The specific preparation manner is as follows: a glass substrate 101 having an indium tin oxide (ITO) anode 110 with a thickness of 1200 Å was cleaned, treated with UV ozone and oxygen plasma, dried in a nitrogen-filled glovebox to remove moisture, then mounted on a substrate holder and placed in a vacuum chamber. Organic layers were sequentially deposited through vacuum thermal evaporation on the ITO anode 110 at a rate of 0.01-10 Å/s and a vacuum degree of about 10⁻⁶ torr. First, HT-18 and a first p-type dopant, i.e. compound 5-1, were co-deposited as a first organic layer 120a with a thickness of 50 Å, wherein the doping proportion of compound 5-1 was 0.5%. Subsequently, HT-18 and compound 3-1 were co-deposited as a second organic layer 120b with a thickness of 50 Å on the first organic layer 120a, wherein the doping proportion of compound 3-1 was 0.5%. The first organic layer 120a and the second organic layer 120b were used together as a hole injection layer 120 with a total thickness of 100 Å. Compound HT-18 was deposited as a hole transporting layer (HTL) 130 with a thickness of 400 Å. Compound EB was deposited as an electron blocking layer (EBL) 140 with a thickness of 50 Å. A red emissive dopant, compound D-1, was doped into a host compound RH to form a red emissive layer (EML) 150 with a thickness of 400 Å, wherein the doping proportion of compound D-1 was 3%. Compound ET and LiQ were co-deposited as an electron transporting layer (ETL) 170 with a thickness of 350 Å, wherein the doping proportion of LiQ was 60%. On the ETL, LiQ with a thickness of 10 Å was deposited as an electron injection layer (EIL) 180. Finally, Al with a thickness of 1200 Å was deposited as a cathode. After evaporation, the device was transferred back to the glovebox and encapsulated with a glass lid as an encapsulation layer 102 to complete the device.

### Example 1-2

The preparation process of Example 1-2 is the same as that of Example 1-1 except that the doping proportion of compound 5-1 in the first organic layer 120a was 1%.

### Example 1-3

The preparation process of Example 1-3 is the same as that of Example 1-1 except that the first organic layer 120a was composed of compound HT-18 and compound 3-1, wherein the doping proportion of compound 3-1 was 2%; the second organic layer 120b was composed of compound HT-18 and compound 5-1, wherein the doping proportion of compound 5-1 was 0.5%.

### Example 1-4

The preparation process of Example 1-4 is the same as that of Example 1-1 except that the first organic layer 120a was composed of compound HT-18 and compound 1-2 and had a thickness of 80 Å, wherein the doping proportion of compound 1-2 was 16%; the second organic layer 120b was composed of compound HT-18 and compound 3-1 and had a thickness of 20 Å, wherein the doping proportion of compound 3-1 was 2%.

### Example 1-5

The preparation process of Example 1-5 is the same as that of Example 1-1 except that the first organic layer 120a was composed of compound HT-18 and compound 1-2 and had a thickness of 80 Å, wherein the doping proportion of compound 1-2 was 16%; the second organic layer 120b was composed of compound HT-18 and compound 4-5 and had a thickness of 20 Å, wherein the doping proportion of compound 4-5 was 3%.

### Example 1-6

The preparation process of Example 1-6 is the same as that of Example 1-1 except that the first organic layer 120a was composed of compound HT-18 and compound 1-2, wherein the doping proportion of compound 1-2 was 16%; the second organic layer 120b was composed of compound HT-18 and compound 4-19, wherein the doping proportion of compound 4-19 was 2%.

### Example 1-7

The preparation process of Example 1-7 is the same as that of Example 1-1 except that the first organic layer 120a was composed of compound HT-18 and compound 1-2, wherein the doping proportion of compound 1-2 was 16%; the second organic layer 120b was composed of compound HT-18 and compound 5-1, wherein the doping proportion of compound 5-1 was 2%.

### Comparative Example 1-1

The preparation process of Comparative Example 1-1 is the same as that of Example 1-1 except that the first organic layer 120a was composed of compound HT-18 and compound 5-1 and had a thickness of 50 Å, wherein the doping proportion of compound 5-1 was 0.5%; the second organic layer 120b was composed of compound HT-18 and compound 5-1 and had a thickness of 50 Å, wherein the doping proportion of compound 5-1 was 0.5%.

### Comparative Example 1-2

The preparation process of Comparative Example 1-2 is the same as that of Example 1-1 except that the first organic layer 120a was composed of compound HT-18 and compound 3-1 and had a thickness of 50 Å, wherein the doping proportion of compound 3-1 was 0.5%; the second organic layer 120b was composed of compound HT-18 and compound 3-1 and had a thickness of 50 Å, wherein the doping proportion of compound 3-1 was 0.5%.

### Comparative Example 1-3

The preparation process of Comparative Example 1-3 is the same as that of Example 1-1 except that the first organic layer 120a was composed of compound HT-18 and compound 5-1 and had a thickness of 50 Å, wherein the doping proportion of compound 5-1 was 1%; the second organic layer 120b was composed of compound HT-18 and compound 5-1 and had a thickness of 50 Å, wherein the doping proportion of compound 5-1 was 1%.

### Comparative Example 1-4

The preparation process of Comparative Example 1-4 is the same as that of Example 1-1 except that the first organic layer 120a was composed of compound HT-18 and compound 3-1 and had a thickness of 50 Å, wherein the doping proportion of compound 3-1 was 2%; the second organic layer 120b was composed of compound HT-18 and compound 3-1 and had a thickness of 50 Å, wherein the doping proportion of compound 3-1 was 2%.

### Comparative Example 1-5

The preparation process of Comparative Example 1-5 is the same as that of Example 1-1 except that the first organic layer 120a was composed of compound HT-18 and compound 1-2 and had a thickness of 50 Å, wherein the doping proportion of compound 1-2 was 16%; the second organic layer 120b was composed of compound HT-18 and compound 1-2 and had a thickness of 50 Å, wherein the doping proportion of compound 1-2 was 16%.

### Comparative Example 1-6

The preparation process of Comparative Example 1-6 is the same as that of Example 1-1 except that the first organic layer 120a was composed of compound HT-18 and compound 4-5 and had a thickness of 50 Å, wherein the doping proportion of compound 4-5 was 3%; the second organic layer 120b was composed of compound HT-18 and compound 4-5 and had a thickness of 50 Å, wherein the doping proportion of compound 4-5 was 3%.

### Comparative Example 1-7

The preparation process of Comparative Example 1-7 is the same as that of Example 1-1 except that the first organic layer 120a was composed of compound HT-18 and compound 4-19 and had a thickness of 50 Å, wherein the doping proportion of compound 4-19 was 2%; the second organic layer 120b was composed of compound HT-18 and compound 4-19 and had a thickness of 50 Å, wherein the doping proportion of compound 4-19 was 2%.

### Comparative Example 1-8

The preparation process of Comparative Example 1-8 is the same as that of Example 1-1 except that the first organic layer 120a was composed of compound HT-18 and compound 5-1 and had a thickness of 50 Å, wherein the doping proportion of compound 5-1 was 2%; the second organic layer 120b was composed of compound HT-18 and compound 5-1 and had a thickness of 50 Å, wherein the doping proportion of compound 5-1 was 2%.

Details of part of the structures of the devices in Example 1-1 to 1-7 and Comparative Examples 1-1 to 1-8 are shown in Table 2 below. The layers using more than one material were obtained by doping different compounds at their weight ratios as recorded.

TABLE 2
Part of the structures of the devices in Example
1-1 to 1-7 and Comparative Examples 1-1 to 1-8

| Device No. | First organic layer | Second organic layer |
|---|---|---|
| Example 1-1 | HT-18:compound 5-1 = 99.5:0.5 (50 Å) | HT-18:compound 3-1 = 99.5:0.5 (50 Å) |
| Example 1-2 | HT-18:compound 5-1 = 99:1 (50 Å) | HT-18:compound 3-1 = 99.5:0.5 (50 Å) |
| Example 1-3 | HT-18:compound 3-1 = 98:2 (50 Å) | HT-18:compound 5-1 = 99.5:0.5 (50 Å) |
| Example 1-4 | HT-18:compound 1-2 = 84:16 (80 Å) | HT-18:compound 3-1 = 98:2 (20 Å) |
| Example 1-5 | HT-18:compound 1-2 = 84:16 (80 Å) | HT-18:compound 4-5 = 97:3 (20 Å) |
| Example 1-6 | HT-18:compound 1-2 = 84:16 (50 Å) | HT-18:compound 4-19 = 98:2 (50 Å) |
| Example 1-7 | HT-18:compound 1-2 = 84:16 (50 Å) | HT-18:compound 5-1 = 98:2 (50 Å) |
| Comparative | HT-18:compound 5-1 = 99.5:0.5 (50 Å) | HT-18:compound 5-1 = 99.5:0.5 (50 Å) |
| Example 1-1 | | |
| Comparative | HT-18:compound 3-1 = 99.5:0.5 (50 Å) | HT-18:compound 3-1 = 99.5:0.5 (50 Å) |
| Example 1-2 | | |
| Comparative | HT-18:compound 5-1 = 99:1 (50 Å) | HT-18:compound 5-1 = 99:1 (50 Å) |
| Example 1-3 | | |
| Comparative | HT-18:compound 3-1 = 98:2 (50 Å) | HT-18:compound 3-1 = 98:2 (50 Å) |
| Example 1-4 | | |
| Comparative | HT-18:compound 1-2 = 84:16 (50 Å) | HT-18:compound 1-2 = 84:16 (50 Å) |
| Example 1-5 | | |
| Comparative | HT-18:compound 4-5 = 97:3 (50 Å) | HT-18:compound 4-5 = 97:3 (50 Å) |
| Example 1-6 | | |
| Comparative | HT-18:compound 4-19 = 98:2 (50 Å) | HT-18:compound 4-19 = 98:2 (50 Å) |
| Example 1-7 | | |
| Comparative | HT-18:compound 5-1 = 98:2 (50 Å) | HT-18:compound 5-1 = 98:2 (50 Å) |
| Example 1-8 | | |

The structures of the compounds used in the devices are shown as follows:

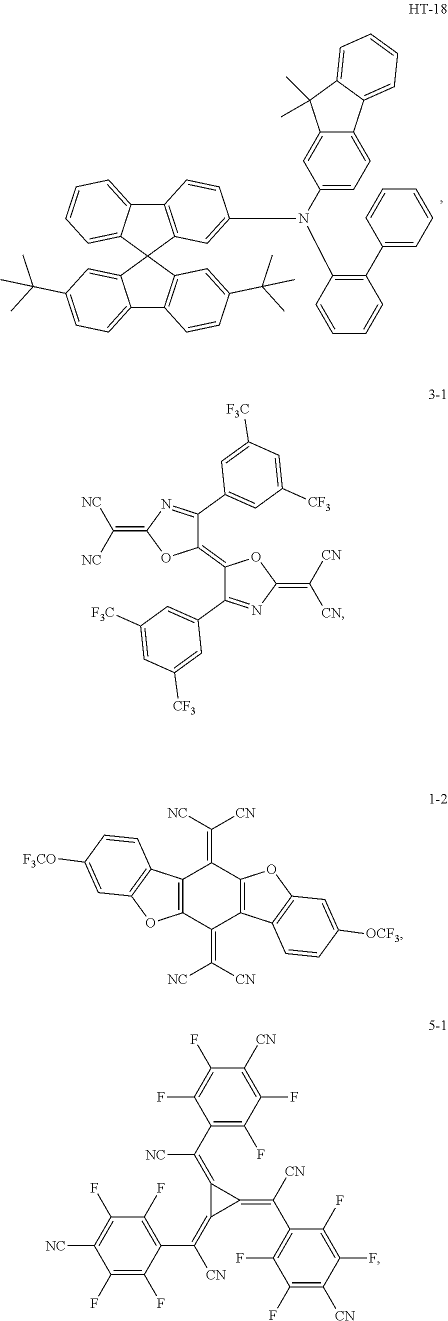 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; N#CC(C#N)=c1nc(-c2cc(C(F)(F)F)cc(C(F)(F)F)c2)/c(=c2\oc(=C(C#N)C#N)nc2-c2cc(C(F)(F)F)cc(C(F)(F)F)c2)o1 ; N#CC(C#N)=c1c2oc3cc(OC(F)(F)F)ccc3c2c(=C(C#N)C#N)c2oc3cc(OC(F)(F)F)ccc3c12 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

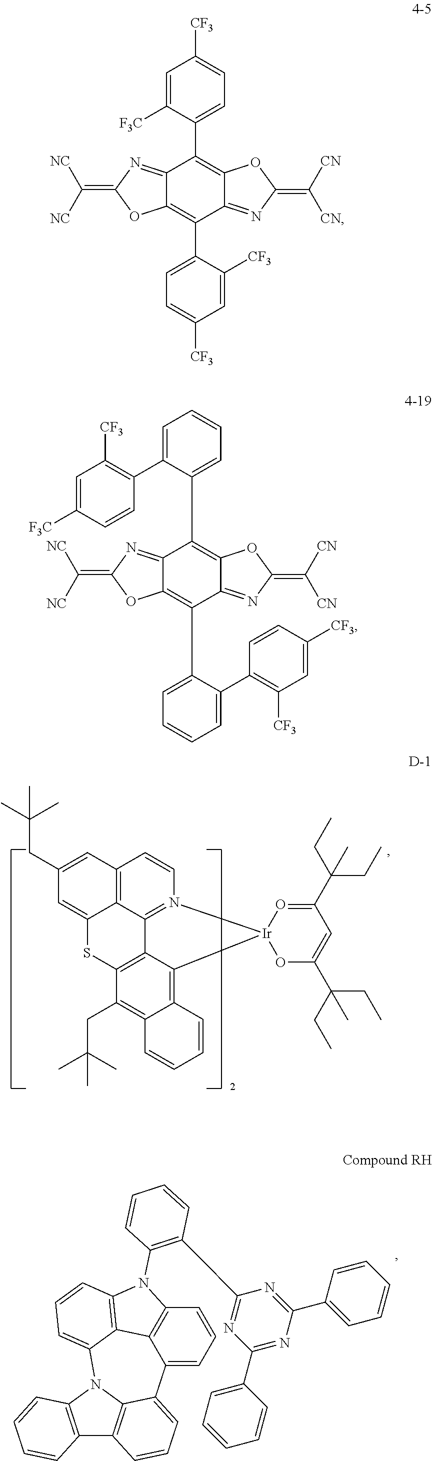

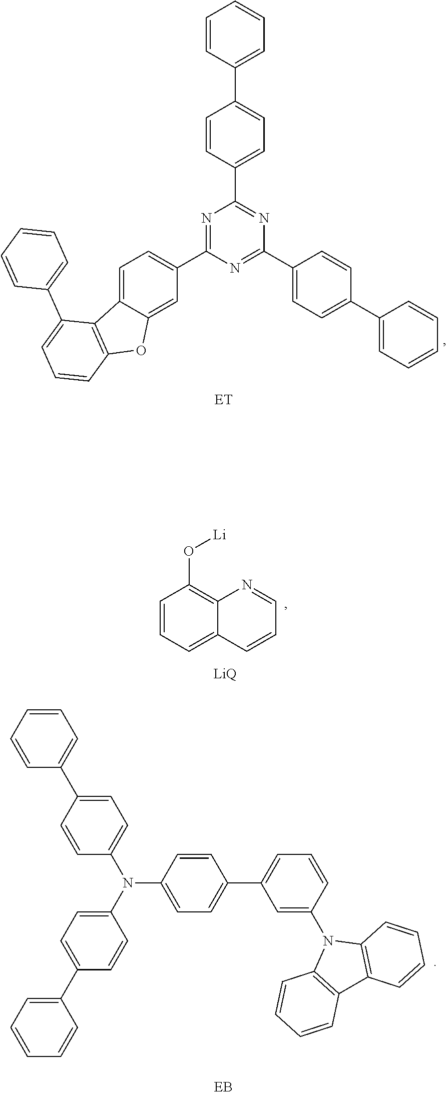

Device performance of Examples 1-1 to 1-7 and Comparative Examples 1-1 to 1-8 was measured. The chromaticity coordinates (CIE), voltage and external quantum efficiency (EQE) were measured at a current density of 10 mA/cm², and the device lifetime (LT97) was the time measured for the brightness of the device to decay to 97% of the initial brightness at a constant current of 80 mA/cm². The data is shown in Table 3.

TABLE 3
Device performance of Examples 1-1 to
1-7 and Comparative Examples 1-1 to 1-8

| | 10 mA/cm² | | | 80 mA/cm² |
|---|---|---|---|---|
| Device No. | CIE (x, y) | Voltage (V) | EQE (%) | LT97 (h) |
| Example 1-1 | (0.701, 0.298) | 3.2 | 29.1 | 200 |
| Example1-2 | (0.701, 0.298) | 3.0 | 27.6 | 260 |
| Example1-3 | (0.701, 0.298) | 3.0 | 28.0 | 250 |
| Example1-4 | (0.700, 0.299) | 3.3 | 31.5 | 221 |
| Example1-5 | (0.700, 0.299) | 3.0 | 28.8 | 191 |
| Example1-6 | (0.701, 0.299) | 3.2 | 30.6 | 220 |
| Example1-7 | (0.701, 0.299) | 3.0 | 29.2 | 210 |
| Comparative | (0.701, 0.298) | 3.2 | 31.2 | 95 |
| Example 1-1 | | | | |
| Comparative | (0.701, 0.298) | 3.6 | 31.7 | 140 |
| Example 1-2 | | | | |
| Comparative | (0.701, 0.298) | 3.0 | 28.8 | 120 |
| Example 1-3 | | | | |
| Comparative | (0.701, 0.298) | 3.0 | 27.2 | 216 |
| Example 1-4 | | | | |
| Comparative | (0.701, 0.299) | 4.0 | 32.6 | 50 |
| Example 1-5 | | | | |
| Comparative | (0.701, 0.299) | 2.9 | 25.9 | 196 |
| Example 1-6 | | | | |
| Comparative | (0.701, 0.299) | 3.0 | 28.2 | 107 |
| Example 1-7 | | | | |
| Comparative | (0.701, 0.299) | 2.9 | 26.8 | 120 |
| Example 1-8 | | | | |

As can be seen from the chromaticity coordinates, the chromaticity coordinates of Examples 1-1 to 1-7 were substantially consistent with the chromaticity coordinates of Comparative Examples 1-1 to 1-8.

OLEDs with a high EQE, low voltage and long lifetime are desired devices, but the comprehensive performance of the device should be considered when the preceding desired performance cannot be satisfied simultaneously. In Example 1-1, the device structure including the first and second organic layers of the present disclosure was used, wherein the first organic layer and the second organic layer were in contact with each other, and the first p-type dopant in the first organic layer and the second p-type dopant in the second organic layer were different. The first p-type dopant was compound 5-1, and had a LUMO energy level of −5.04 eV; the second p-type dopant was compound 3-1 and had a LUMO energy level of −4. 91 eV; the LUMO energy levels of both dopants were less than −4.35 eV. As shown in Table 3, Example 1-1 achieved a high EQE of 29.1%, a long lifetime of 200 h and a low drive voltage of 3.2 V. Example 1-1 was compared with Comparative Example 1-1 and Comparative Example 1-2 respectively. (1) The first p-type dopant and the second p-type dopant in Comparative Example 1-1 both were compound 5-1, which was the same as the first dopant in Example 1-1, and the doping proportion of compound 5-1 was the same as that of the first dopant in the first organic layer in Example 1-1. Compared with Comparative Example 1-1, the lifetime of Example 1-1 was improved by 1.1 times, and both Example 1-1 and Comparative Example 1-1 had substantially equivalent voltages. (2) The first p-type dopant and the second p-type dopant in Comparative Example 1-2 both were compound 3-1, which was the same as the second dopant in Example 1-1, and the doping proportion of compound 3-1 was the same as that of the second dopant in the second organic layer in Example 1-1. Compared with Comparative Example 1-2, the lifetime of Example 1-1 was improved by 42.8%, and the drive voltage was reduced by 0.4 V. Compared with Comparative Example 1-1 and Comparative Example 1-2, although the EQE of Example 1-1 was reduced by about 8%, the EQE of Example 1-1 also reached a high EQE level of 29.1%, and more importantly, the lifetime of Example 1-1 was significantly improved. Therefore, the comprehensive performance of the device of Example 1-1 was more excellent.

Example 1-2 differed from Example 1-1 in that the doping proportion of the first p-type dopant of the first organic layer was increased from 0.5% in Example 1-1 to 1%. As shown in Table 3, Example 1-2 achieved a high EQE of 27.6%, the lifetime was further improved and reached an ultra-long lifetime of 260 h, and a lower drive voltage was also achieved. Example 1-2 was compared with Comparative Example 1-3 and Comparative Example 1-2 respectively. The first p-type dopant and the second p-type dopant in Comparative Example 1-3 both were compound 5-1, which was the same as the first dopant in Example 1-2, and the doping proportion of compound 5-1 was the same as that of the first dopant in the first organic layer in Example 1-2. The first p-type dopant and the second p-type dopant in Comparative Example 1-2 both were compound 3-1, which was the same as the second dopant in Example 1-2, and the doping proportion of compound 3-1 was the same as that of the second dopant in the second organic layer in Example 1-2. Compared with Comparative Example 1-2 and Comparative Example 1-3, the lifetime of Example 1-2 was improved by 85.7% and 116.7%, respectively. Compared with Comparative Example 1-2, the drive voltage of Example 1-2 was reduced by 0.6 V. Compared with Comparative Example 1-2 and Comparative Example 1-3, although the EQE of Example 1-2 was slightly lower, the EQE of Example 1-2 also reached a high EQE level, and more importantly, the lifetime of Example 1-2 was significantly improved. Therefore, the comprehensive performance of the device of Example 1-2 was more excellent.

In Example 1-3, the first p-type dopant in the first organic layer was compound 3-1, wherein the doping proportion of compound 3-1 was 2%; the second p-type dopant in the second organic layer was compound 5-1, wherein the doping proportion of compound 5-1 was 0.5%; and the first organic layer and the second organic layer were in contact with each other. The first p-type dopant and the second p-type dopant in Comparative Example 1-4 both were compound 3-1, which was the same as the first dopant in Example 1-3, and the doping proportion of compound 3-1 was the same as that of the first dopant in the first organic layer in Example 1-3. The first p-type dopant and the second p-type dopant in Comparative Example 1-1 both were compound 5-1, which was the same as the second dopant in Example 1-3, and the doping proportion of compound 5-1 was the same as that of the second dopant in the second organic layer in Example 1-3. Compared with Comparative Example 1-1 and Comparative Example 1-4, the voltage of Example 1-3 was substantially equivalent to the voltages of Comparative Example 1-1 and Comparative Example 1-4, the lifetime was improved by 163.1% and 15.7%, respectively, and especially the lifetime was further improved on the basis that Comparative Example 1-4 had a long lifetime. Compared with Comparative Example 1-1, although the EQE of Example 1-3 was slightly lower, the EQE of Example 1-3 also reached a high EQE level of 28%, and more importantly, the lifetime of Example 1-3 was significantly improved. Therefore, the comprehensive performance of the device of Example 1-3 was more excellent.

In Example 1-4, the device structure including the first and second organic layers of the present disclosure was used, wherein the first organic layer and the second organic layer were in contact with each other, and the first p-type dopant in the first organic layer and the second p-type dopant in the second organic layer were different. The first p-type dopant was compound 1-2, and had a LUMO energy level of −4.63 eV; the second p-type dopant was compound 3-1 and had a LUMO energy level of −4. 91 eV; the LUMO energy levels of both dopants were less than −4.35 eV. Compared with Comparative Example 1-5 in which the first p-type dopant and the second p-type dopant both were compound 1-2, the voltage of Example 1-4 was reduced by 0.7 V, the lifetime was greatly improved by 342%, and although the EQE was slightly lower, the EQE of Example 1-4 also reached an ultra-high EQE level of 31.5%, indicating that the device of Example 1-4 was a device with excellent comprehensive performance. Compared with Comparative Example 1-4 in which the first p-type dopant and the second p-type dopant both were compound 3-1, the EQE of Example 1-4 was improved by 16%, the lifetime was improved by 2%, and the voltage was slightly improved by 0.3 V. Therefore, the comprehensive performance the device of Example 1-4 was more excellent.

In Example 1-5, the device structure including the first and second organic layers of the present disclosure was used, wherein the first organic layer and the second organic layer were in contact with each other, and the first p-type dopant in the first organic layer and the second p-type dopant in the second organic layer were different. The first p-type dopant was compound 1-2, and had a LUMO energy level of −4.63 eV; the second p-type dopant was compound 4-5 and had a LUMO energy level of −5.17 eV; the LUMO energy levels of both dopants were less than −4.35 eV. Compared with Comparative Example 1-5 in which the first p-type dopant and the second p-type dopant both were compound 1-2, the voltage of Example 1-5 was reduced by 1 V, the lifetime was greatly improved by 282%, and although the EQE was slightly lower, the EQE of Example 1-5 also reached 28.8%, indicating that the device of Example 1-5 was a device with excellent comprehensive performance. Compared with Comparative Example 1-6 in which the first p-type dopant and the second p-type dopant both were compound 4-5, the EQE of Example 1-5 was improved by 11%, and the voltage and the lifetime of the Example 1-5 were substantially equivalent to those of Comparative Example 1-6. Therefore, the comprehensive performance of the device of Example 1-5 was more excellent.

In Example 1-6, the device structure including the first and second organic layers of the present disclosure was used, wherein the first organic layer and the second organic layer were in contact with each other, and the first p-type dopant in the first organic layer and the second p-type dopant in the second organic layer were different. The first p-type dopant was compound 1-2, and had a LUMO energy level of −4.63 eV; the second p-type dopant was compound 4-19 and had a LUMO energy level of −5.12 eV; the LUMO energy levels of both dopants were less than −4.35 eV. Compared with Comparative Example 1-5 in which the first p-type dopant and the second p-type dopant both were compound 1-2, the voltage of Example 1-6 was reduced by 0.8 V, the lifetime was greatly improved by 340%, and although the EQE was slightly lower, the EQE of Example 1-6 also reached 30.6%. Therefore, the device of Example 1-6 was a device with very excellent comprehensive performance. Compared with Comparative Example 1-7 in which the first p-type dopant and the second p-type dopant both were compound 4-19, the EQE of Example 1-6 was improved by 9%, the lifetime was improved by 106%, and the voltage was slightly improved by 0.2 V. Therefore, the comprehensive performance the device of Example 1-6 was more excellent.

In Example 1-7, the first p-type dopant in the first organic layer was compound 1-2, the second p-type dopant in the second organic layer was compound 5-1, the first organic layer and the second organic layer were in contact with each other, and the LUMO energy levels of both the first p-type dopant and the second p-type dopant were less than −4.35 eV. Compared with Comparative Example 1-5 in which the first p-type dopant and the second p-type dopant both were compound 1-2, the voltage of Example 1-7 was reduced by 1 V, the lifetime was greatly improved by 320%, and although the EQE was slightly lower, the EQE of Example 1-7 also reached 29.2%. Therefore, the device of Example 1-7 was a device with very excellent comprehensive performance. Compared with Comparative Example 1-8 in which the first p-type dopant and the second p-type dopant both were compound 5-1, the EQE of Example 1-7 was improved by 9%, the lifetime was greatly improved by 75%, and the voltage of the Example 1-7 was substantially equivalent to that of Comparative Example 1-8.

Through the above comparison, it is surprisingly found that the OLED with excellent comprehensive performance can be obtained by using the organic electroluminescent device including the specific first and the second organic layers of the present disclosure.

### Example 2-1

A stacked organic electroluminescent device 400 was prepared, as shown in FIG. 4 (wherein the hole blocking layers 160a and 160b are omitted in this example and the persons skilled in the art may add hole blocking layers as needed). The specific preparation manner is as follows: a glass substrate 101 on which a patterned indium tin oxide (ITO) anode 110 with a thickness of 1200 Å was previously coated was cleaned with ultrapure water, and the ITO surface was treated with UV ozone and oxygen plasma. The substrate was dried in a nitrogen-filled glovebox to remove moisture, then mounted on a holder and placed in a vacuum chamber. Organic layers specified below were sequentially deposited through vacuum thermal evaporation on the ITO anode 110 at a rate of 0.01 to 10 Å/s and a vacuum degree of about 1*10⁻⁶ tort. First, the first emissive unit 1101 was deposited. HT-18 and compound 1-2 were co-deposited as a first organic layer 121a with a thickness of 80 Å, wherein the doping proportion of compound 1-2 was 16%. Subsequently, HT-18 and compound 3-1 were co-deposited as a second organic layer 122b with a thickness of 20 Å on the first organic layer 121a, wherein the doping proportion of compound 3-1 was 3%. The first organic layer 121a and the second organic layer 122a were used together as a hole injection layer 220a with a total thickness of 100 Å. Compound HT-18 was deposited as a hole transporting layer (HTL) 130a with a thickness of 400 Å. Compound EB was deposited as an electron blocking layer (EBL) 140a with a thickness of 50 Å on the HTL. A red emissive dopant, compound D-1, was doped into a host compound RH to form a red emissive layer (EML) 150a with a thickness of 400 Å, wherein the doping proportion of compound D-1 was 3%. Compound ET and LiQ were co-deposited as an electron transporting layer (ETL) 170a with a thickness of 350 Å, wherein the doping proportion of LiQ was 60%. The charge generation layer 1102 was deposited on the ETL. Metal Yb with a thickness of 15 Å was deposited as an n-type charge generation layer 210, and then compound 1-2 with a thickness of 30 Å was deposited as a p-type charge generation layer 310. The second emissive unit 1103 was deposited. HT-18 and compound 1-2 were co-deposited as a first organic layer 121b with a thickness of 80 Å, wherein the doping proportion of compound 1-2 was 16%. Subsequently, HT-18 and compound 3-1 were co-deposited as a second organic layer 122b with a thickness of 20 Å on the first organic layer 121b, wherein the doping proportion of compound 3-1 was 3%. The first organic layer 121b and the second organic layer 122b were used together as a hole injection layer 220b with a total thickness of 100 Å. Compound HT-18 was deposited as a hole transporting layer (HTL) 130b with a thickness of 400 Å. Compound EB was deposited as an electron blocking layer (EBL) 140b with a thickness of 50 Å. The red emissive dopant, compound D-1, was doped into the host compound RH to form a red emissive layer (EML) 150b with a thickness of 400 Å, wherein the doping proportion of compound D-1 was 3%. Compound ET and LiQ were co-deposited as an electron transporting layer (ETL) 170b with a thickness of 350 Å, wherein the doping proportion of LiQ was 60%. Finally, compound LiQ with a thickness of 10 Å was deposited as an electron injection layer (EIL) 180, and aluminum with a thickness of 1200 Å was deposited as a cathode 190. After the device was prepared, the device was transferred back to the glovebox and encapsulated with a glass lid as an encapsulation layer 102 to complete the device. It is to be noted that the above device structure is only illustrative and is not intended to limit the description of the present disclosure. For example, the hole injection layer 220a in the first emissive unit 1101 may use a structure different from the structure of the hole injection layer 220b in the second emissive unit 1103. For another example, the second emissive unit 1103 may use emissive materials of other colors and other host compounds as well as corresponding mating transporting materials and device structures.

### Comparative Example 2-1

The preparation process of Comparative Example 2-1 is the same as that of Example 2-1 except that the first organic layer 121a in the first emissive unit and the first organic layer 121b in the second emissive unit both were composed of HT-18 and compound 3-1 and had a thickness of 80 Å, wherein the doping proportion of compound 3-1 was 3%; the second organic layer 122a in the first emissive unit and the second organic layer 122b in the second emissive unit both were composed of HT-18 and compound 3-1 and had a thickness of 20 Å, wherein the doping proportion of compound 3-1 was 3%.

### Comparative Example 2-2

The preparation process of Comparative Example 2-2 is the same as that of Example 2-1 except that the first organic layer 121a in the first emissive unit and the first organic layer 121b in the second emissive unit both were composed of HT-18 and compound 1-2 and had a thickness of 80 Å, wherein the doping proportion of compound 1-2 was 16%; the second organic layer 122a in the first emissive unit and the second organic layer 122b in the second emissive unit both were composed of HT-18 and compound 1-2 and had a thickness of 20 Å, wherein the doping proportion of compound 1-2 was 16%.

Details of part of the structures of the devices in Example 2-1 and Comparative Examples 2-1 to 2-2 are shown in Table 4 below. The layers using more than one material were obtained by doping different compounds at their weight ratios as recorded.

TABLE 4
Part of the structures of the devices in Example 2-1 and Comparative Examples 2-1 to 2-2

| | First emissive unit | | Second emissive unit | |
|---|---|---|---|---|
| | First organic | Second organic | First organic | Second organic |
| Device No. | layer 121a | layer 122a | layer 121b | layer 122b |
| Example 2-1 | HT-18:compound 1-2 = | HT-18:compound 3-1 = | HT-18:compound 1-2 = | HT-18:compound 3-1 = |
| | 84:16 (80 Å) | 97:3 (20 Å) | 84:16 (80 Å) | 97:3 (20 Å) |
| Comparative | HT-18:compound 3-1 = | HT-18:compound 3-1 = | HT-18:compound 3-1 = | HT-18:compound 3-1 = |
| Example 2-1 | 97:3 (80 Å) | 97:3 (20 Å) | 97:3 (80 Å) | 97:3 (20 Å) |
| Comparative | HT-18:compound 1-2 = | HT-18:compound 1-2 = | HT-18:compound 1-2 = | HT-18:compound 1-2 = |
| Example 2-2 | 84:16 (80 Å) | 84:16 (20 Å) | 84:16 (80 Å) | 84:16 (20 Å) |

Device performance of Example 2-1 and Comparative Examples 2-1 to 2-2 was measured. The chromaticity coordinates (CIE), voltage and external quantum efficiency (EQE) were measured at a brightness of 2000 cd/m², and the device lifetime was the time for 2000 cd/m² to decay to 97% of the initial brightness. The data is shown in Table 5.

TABLE 5
Device performance of Example 2-1
and Comparative Examples 2-1 to 2-2

| | 2000 cd/m² | | | |
|---|---|---|---|---|
| Device No. | CIE (x, y) | Voltage (V) | EQE (%) | LT97 (h) |
| Example 2-1 | (0.701, 0.298) | 5.7 | 61.7 | 25,300 |
| Comparative | (0.701, 0.298) | 5.7 | 50.6 | 24,400 |
| Example 2-1 | | | | |
| Comparative | (0.701, 0.298) | 5.9 | 58.4 | 21,600 |
| Example 2-2 | | | | |

Example 2-1 was a stacked OLED with the connection by the charge generation layer, wherein the first emissive unit and the second emissive unit connected by the charge generation layer both included the same first and the second organic layers, and the first p-type dopant included in the first organic layer was different from the second p-type dopant included in the second organic layer, which were compound 1-2 and compound 3-1, respectively. Comparative Example 2-1 and Comparative Example 2-2 were also stacked OLEDs having the same device structure, but both the first and the second organic layers in each of the first emissive unit and the second emissive unit included the same p-type dopant, Comparative Example 2-1 used compound 3-1 as the p-type dopant and Comparative Example 2-2 used compound 1-2 as the p-type dopant.

As can be seen from the device performance data in Table 5, Example 2-1 including the first and the second organic layers specified in the present application achieved a high EQE of 61.7% at 2000 cd/m2, a low voltage of 5.7 V and a long lifetime of 25300 h. Compared with Comparative Example 2-1 in which the first organic layer and the second organic layer both included compound 3-1, the lifetime of Example 2-1 was improved by 4%, the voltage was substantially equivalent to the voltage of Comparative Example 2-1, and the EQE was improved by 22%. Compared with Comparative Example 2-2 in which the first organic layer and the second organic layer both included compound 1-2, the voltage of Example 2-1 was reduced by 0.2 V, the efficiency was improved by 6%, and the lifetime was significantly improved by 17%.

As can be seen, the stacked device structure including the specific first and the second organic layers of the present disclosure can also significantly improve the comprehensive performance of the stacked device.

### Example 3-1

An organic electroluminescent device 300 was prepared, as shown in FIG. 3. The specific preparation manner is as follows: a glass substrate 101 having an indium tin oxide (ITO) anode 110 with a thickness of 800 Å was cleaned, treated with UV ozone and oxygen plasma, dried in a nitrogen-filled glovebox to remove moisture, then mounted on a substrate holder and placed in a vacuum chamber. Organic layers were sequentially deposited through vacuum thermal evaporation on the ITO anode 110 at a rate of 0.01-10 Å/s and a vacuum degree of about 10⁻⁶ torr. First, HT-18 and a first p-type dopant, i.e. compound 1-2, were co-deposited as a first organic layer 120a with a thickness of 80 Å, wherein the doping proportion of compound 1-2 was 16%. Subsequently, HT-18 and compound 3-1 were co-deposited as a second organic layer 120b with a thickness of 20 Å on the first organic layer 120a, wherein the doping proportion of compound 3-1 was 3%. The first organic layer 120a and the second organic layer 120b were used together as a hole injection layer 120 with a total thickness of 100 Å. Compound HT-18 was deposited as a hole transporting layer (HTL) 130 with a thickness of 250 Å. Compound HT-1 was deposited as an electron blocking layer (EBL) 140 with a thickness of 50 Å. A blue emissive dopant, compound D-2, and a blue host compound BH were co-deposited as a blue emissive layer (EML) 150 with a thickness of 20 Å, wherein the doping proportion of compound D-2 was 4%. Compound HB was deposited as a hole blocking layer (HBL) 160 with a thickness of 50 Å. Compound ET and LiQ were co-deposited as an electron transporting layer (ETL) 170 with a thickness of 300 Å on the HBL, wherein the doping proportion of LiQ was 60%. On the ETL, LiQ with a thickness of 10 Å was deposited as an electron injection layer (EIL). Finally, Al with a thickness of 1200 Å was deposited as a cathode 190. After evaporation, the device was transferred back to the glovebox and encapsulated with a glass lid as an encapsulation layer 102 to complete the device.

### Comparative Example 3-1

The preparation process of Comparative Example 3-1 is the same as that of Example 3-1 except that the first organic layer 120a was composed of compound HT-18 and compound 3-1 and had a thickness of 80 Å, wherein the doping proportion of compound 3-1 was 3%; the second organic layer was composed of compound HT-18 and compound 3-1 and had a thickness of 20 Å, wherein the doping proportion of compound 3-1 was 3%.

Details of part of the structures of the devices in Example 3-1 and Comparative Example 3-1 are shown in Table 6 below. The layers using more than one material were obtained by doping different compounds at their weight ratios as recorded.

TABLE 6
Part of the structures of the devices in
Example 3-1 and Comparative Example 3-1

| | First emissive | Second emissive |
|---|---|---|
| Device No. | unit 120a | unit 120b |
| Example 3-1 | HT-18:compound 1-2 = | HT-18:compound 3-1 = |
| | 84:16 (80 Å) | 97:3 (20 Å) |
| Comparative | HT-18:compound 3-1 = | HT-18:compound 3-1 = |
| Example 3-1 | 97:3 (80 Å) | 97:3 (20 Å) |

The structures of the new compounds used in the device are shown as follows:

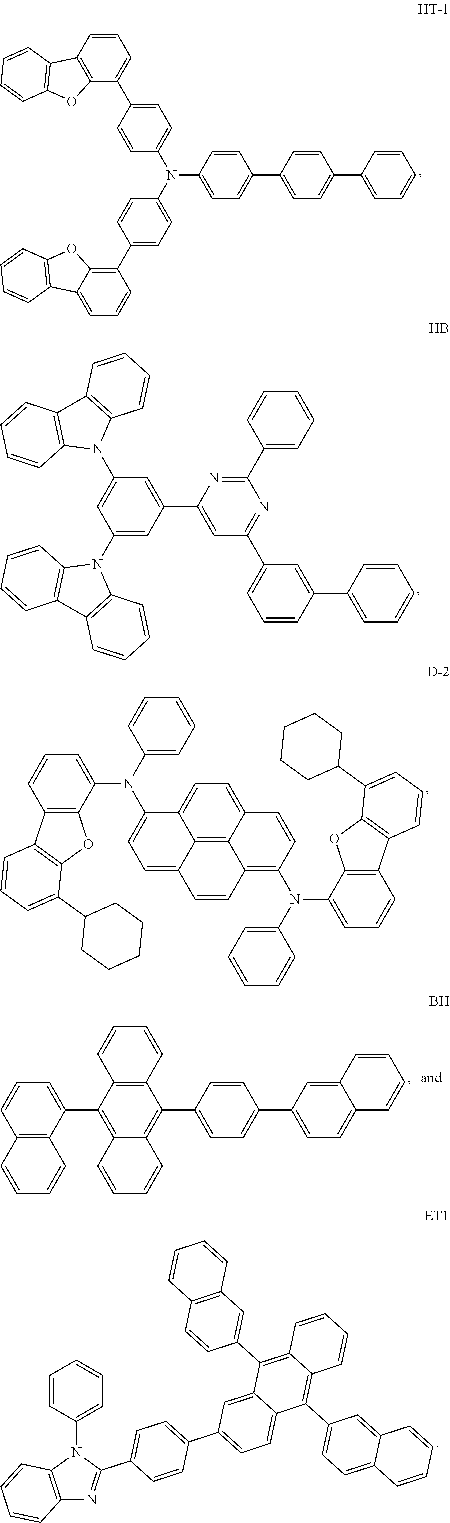

Device performance of Example 3-1 and Comparative Example 3-1 was measured. The chromaticity coordinates (CIE), voltage and external quantum efficiency (EQE) were measured at a current density of 10 mA/cm², and the device lifetime (LT97) was the time measured for the brightness of the device to decay to 97% of the initial brightness at a constant current of 80 mA/cm². The data is shown in Table 7.

TABLE 7
Device performance of Example 3-1 and Comparative Example 3-1

| | 10 mA/cm² | | | 80 mA/cm² |
|---|---|---|---|---|
| Device No. | CIE (x, y) | Voltage (V) | EQE (%) | LT97 (h) |
| Example 3-1 | (0.137, 0.098) | 4.0 | 8.8 | 84 |
| Comparative | (0.137, 0.098) | 3.9 | 8.1 | 70 |
| Example 3-1 | | | | |

Example 3-1 and Comparative Example 3-1 were blue fluorescent devices, and the chromaticity coordinates of Example 3-1 were substantially consistent with those of Comparative Example 3-1, as shown in Table 7. In Example 3-1, the device included the first organic layer and the second organic layer, and the first p-type dopant included in the first organic layer and the second p-type dopant included in the second organic layer were different. The first organic layer and the second organic layer of Comparative Example 3-1 included the same p-type dopant. As can be seen from the comparison of device data in Table 7, the device voltage of Example 3-1 was substantially equivalent to that of Comparative Example 3-1, but the lifetime of Example 3-1 was greatly improved by 20%, and the EQE was improved by 8.6%. It is indicated that the first and second organic layers including specific structures in the present disclosure have a remarkable effect on the improvement of the comprehensive performance of the device.

In summary, the present application provides a new organic electroluminescent device and relates to a first organic layer and a second organic layer having specific structures, wherein the first organic layer includes a first p-type dopant and the second organic layer includes a second p-type dopant, the first p-type dopant and the second p-type dopant are different, and the first organic layer and the second organic layer are in contact with each other. The organic electroluminescent device with the above specific structure has a remarkable effect on the improvement of the comprehensive performance of the device.

It is to be understood that various embodiments described herein are merely examples and not intended to limit the scope of the present disclosure. Therefore, it is apparent to the persons skilled in the art that the present disclosure as claimed may include variations of specific embodiments and preferred embodiments described herein. Many of materials and structures described herein may be substituted with other materials and structures without departing from the spirit of the present disclosure. It is to be understood that various theories as to why the present disclosure works are not intended to be limitative.

What is claimed is:

1. An organic electroluminescent device, comprising an anode, a cathode, and a hole transporting region disposed between the anode and the cathode,
wherein the hole transporting region comprises a first organic layer and a second organic layer;
the first organic layer comprises a first p-type dopant;
the second organic layer comprises a second p-type dopant;
the first p-type dopant is different from the second p-type dopant;
the lowest unoccupied molecular orbital (LUMO) energy levels of the first p-type dopant and the second p-type dopant are less than or equal to −4.35 eV; and
the first organic layer is in contact with the second organic layer.

2. The organic electroluminescent device according to claim 1, wherein the sum of the thickness of the first organic layer and the thickness of the second organic layer is not greater than 100 nm;
preferably, the sum of the thickness of the first organic layer and the thickness of the second organic layer is not greater than 30 nm;
more preferably, the sum of the thickness of the first organic layer and the thickness of the second organic layer is not greater than 20 nm.

3. The organic electroluminescent device according to claim 1, wherein the first p-type dopant and the second p-type dopant are molecular p-type dopants.

4. The organic electroluminescent device according to claim 1, wherein the LUMO energy level of the first p-type dopant and/or the LUMO energy level of the second p-type dopant are less than or equal to −4.5 eV;
preferably, the LUMO energy level of the first p-type dopant and/or the LUMO energy level of the second p-type dopant are less than or equal to −4.6 eV.

5. The organic electroluminescence device according to claim 1, wherein the first organic layer is in contact with the anode.

6. The organic electroluminescent device according to claim 1, wherein the doping proportion of the first p-type dopant in the first organic layer is the same as or different from the doping proportion of the second p-type dopant in the second organic layer.

7. The organic electroluminescent device according to claim 1, wherein the LUMO energy level of the first p-type dopant is greater than or equal to the LUMO energy level of the second p-type dopant.

8. The organic electroluminescent device according to claim 1, wherein the LUMO energy level of the first p-type dopant is less than or equal to the LUMO energy level of the second p-type dopant.

9. The organic electroluminescent device according to claim 1, further comprising an emissive layer disposed between the anode and the cathode.

10. The organic electroluminescent device according to claim 9, wherein the emissive layer comprises an emissive material, and the emissive material is a phosphorescent material, a fluorescent material or a delayed fluorescent material.

11. The organic electroluminescent device according to claim 1, wherein the hole transporting region further comprises a third organic layer, and the third organic layer comprises a third p-type dopant;
preferably, the third p-type dopant is the same as or different from the first p-type dopant and/or the third p-type dopant is the same as or different from the second p-type dopant.

12. The organic electroluminescent device according to claim 1, further comprising a charge generation layer, wherein the charge generation layer comprises a p-type charge generation layer.

13. The organic electroluminescent device according to claim 12, wherein the p-type charge generation layer comprises the first p-type dopant or the second p-type dopant.

14. The organic electroluminescence device according to claim 12, wherein the first organic layer or the second organic layer is in contact with the p-type charge generation layer.

15. The organic electroluminescent device according to claim 1, wherein the first organic layer further comprises a first organic material, and the second organic layer further comprises a second organic material;
the first organic material is the same as or different from the second organic material.

16. The organic electroluminescent device according to claim 15, wherein the highest occupied molecular orbital (HOMO) energy level of the first organic material and/or the HOMO energy level of the second organic material are less than −4.5 eV;
preferably, the HOMO energy level of the first organic material and/or the HOMO energy level of the second organic material are less than −4.8 eV.

17. The organic electroluminescent device according to claim 15, wherein the first organic material and/or the second organic material comprise a monotriarylamine structural unit or a bistriarylamine structural unit;
preferably, the first organic material and/or the second organic material comprise any one or more chemical structural units selected from the group consisting of: a monotriarylamine-carbazole structural unit, a monotriarylamine-thiophene structural unit, a monotriarylamine-furan structural unit, a monotriarylamine-fluorene structural unit, a bistriarylamine-carbazole structural unit, a bistriarylamine-thiophene structural unit, a bistriarylamine-furan structural unit, and a bistriarylamine-fluorene structural unit.

18. An electronic assembly, comprising the organic electroluminescent device according to claim 1.
